(19) United States
(12) Patent Application Publication
(10) Pub. No.: US 2010/0052795 A1
(43) Pub. Date: Mar. 4, 2010

(54) SEMICONDUCTOR INTEGRATED CIRCUIT

(75) Inventors: Takahiro Nakamura, Kodaira (JP); Tomomitsu Kitamura, Takasaki (JP); Taizo Yamawaki, Tokyo (JP); Takayasu Norimatsu, Tachikawa (JP); Toshiya Uozumi, Takasaki (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/540,248

(22) Filed: Aug. 12, 2009

(30) Foreign Application Priority Data
Aug. 28, 2008 (JP) 2008-219395

(51) Int. Cl. H03L 7/099

(52) U.S. Cl. 331/10

(57) ABSTRACT

The present invention provides a semiconductor integrated circuit capable of reducing a chip occupied area and reducing variations in control gain of a digitally controlled oscillator. The semiconductor integrated circuit is equipped with the digitally controlled oscillator. The digitally controlled oscillator comprises oscillation transistors and a resonant circuit. The resonant circuit comprises inductances, a frequency coarse-tuning variable capacitor array and a frequency fine-tuning variable capacitor array. The frequency coarse-tuning variable capacitor array comprises a plurality of coarse-tuning capacitor unit cells. The frequency fine-tuning variable capacitor array comprises a plurality of fine-tuning capacitor unit cells. The capacitance values of the coarse-tuning capacitor unit cells of the frequency coarse-tuning variable capacitor array are set in accordance with a binary weight 2^{M-1}. The capacitance values of the fine-tuning capacitor unit cells of the frequency fine-tuning variable capacitor array are also set in accordance with a binary weight 2^{N-1}.

### CLAIM OF PRIORITY

The present application claims priority from Japanese application JP 2008-219395 filed on Aug. 28, 2008, the content of which is hereby incorporated by reference into this application.

### FIELD OF THE INVENTION

The present invention relates to a semiconductor integrated circuit equipped with a digitally controlled oscillator (DCO), and particularly to a technology beneficial to reduce variations in control gain K_{DCO} of the digitally controlled oscillator (DCO).

### BACKGROUND OF THE INVENTION

In information apparatuses such as wireless communication equipment, a storage device and the like, an oscillator whose oscillation frequency is variably controlled is an essential circuit. There has been a demand for miniaturization of a communication semiconductor integrated circuit (IC) with developments in information apparatuses Particularly, in a wireless communication IC used in a cellular phone, a wireless LAN (Local Area Network) and the like, there has been a growing need for technology for integrating an RF circuit for processing a radio frequency (RF) signal and a BB circuit for processing a baseband (BB) signal into an IC chip in the form of one chip.

An all digital PLL (AD-PLL) that uses a digitally controlled oscillator (DCO) with the demand of a highly integrated RF circuit has been described in a non-patent document 1 described below. Compared to a voltage controlled oscillator (VCO) in which a varactor supplied with an analog tuning voltage is used as an LC tank having cross-coupled transistors for an RF oscillator, an all digital PLL (AD-PLL) that adopts a digitally controlled oscillator (DCO) using a varactor array supplied with digital tuning control signals is expected to be low in phase noise.

A digitally controlled oscillator (DCO) used in a digital PLL in a manner similar to the non-patent document 1 has been described even in a non-patent document 2 described below. Frequency tuning of the digitally controlled oscillator (DCO) is realized by a PTV bank per binary weight, an acquisition bank per binary weight and a tracking bank per unit weight, which use quantization capacity of an LC tank-based oscillator. The PTV bank is used in a calibration mode for accommodating factors of variations in process/voltage/temperature (PTV) for a CMOS process. The acquisition bank is used for channel selection. The tracking bank is used between actual transmission and reception. The tracking bank comprises an integral part and a decimal or fraction part. The decimal part is used in high-speed dithering to increase frequency resolution. A minimum frequency shift width Δf_{LSB} of the PTV bank per binary weight is set to 2316 kHz. A minimum frequency shift width Δf_{LSB} of the acquisition bank per binary weight is set to 461 kHz. The tracking bank of the integral part per unit weight and the tracking bank of the decimal part per unit weight are respectively set to 23 kHz.

A dynamic element matching (DEM) method for improving linearity of digital signal to frequency conversion due to errors in capacitances of tracking banks per unit weight caused by an IC's manufacturing process has been described in the non-patent document 2. In the tracking bank, the use or non-use of capacitors is determined according to on/off of switches in a switch matrix. According to the dynamic element matching (DEM) method, the location of each on switch circulates in each clock cycle although the total number of on switches in a matrix switch of a tracking bank relative to the same digital input signal remains unchanged.

Further, the non-patent documents 1 and 2 also have described that follow-up minority bit is supplied to the input of a ΣΔ modulator to control the digitally controlled oscillator (DCO) by the output of the ΣΔ modulator, whereby spurious tones are diffused into second-order and third-order high frequencies of the ΣΔ modulator to reduce phase noise.

A layout technology for locating first and second sections at approximately the same distances diagonally from the point of center of a geometric arrangement in order to improve matching between capacitor arrays used in a successive approximation analog-to-digital converter has been described in the patent document 1.

### [Non-Patent Document 1]

Robert Bogdan Staszewski et al, “All-Digital TX Frequency Synthesizer and Discrete-Time Receiver for Bluetooth Radio in 130-nm CMOS”, IEEE Journal of SOLID-STATE CIRCUITS, VOL. 39, NO. 12, DECEMBER 2004, PP. 2278-2291

### [Non-Patent Document 2]

Robert Bogdan Staszewski et al, “Digitally Controlled Oscillator (DCO)—Based Architecture for RF Frequency Synthesis in a Deep-Submicrometer CMOS Process”, IEEE TRANSACTIONS ON CIRCUITS AND SYETEMS-II: ANALOG AND DIGITAL SIGNAL PROCESSING, VOL. 50, NO. 11, NOVEMBER 2003, PP. 815-828

### [Patent Document 1]

Japanese Unexamined Patent Application Publication (Translation of PCT Application) No. 2002-517095

### SUMMARY OF THE INVENTION

Prior to the present invention, the present inventors et al. have been involved in the study and development of an RFIC mountable in a cellular phone and a 5 GHz wireless LAN corresponding to a multimode for GSM (Global System for Mobile communication) and WCDMA (Wideband Code Division Multiple Access). With the progress of a CMOS micro-fabrication process, attention has been given to the development of an SoC (System on Chip) IC in which an RF circuit and a BB circuit are integrated into one chip, and attention has been given even to an all digital PLL (AD-PLL) that adopts a digitally controlled oscillator (DCO).

On the other hand, a local oscillator (LO) is necessary for an RF transceiver both to transmit and to receive RF signals. The local oscillator is used to downconvert an RF frequency to an IF frequency or a baseband frequency and upconvert an IF frequency or a baseband frequency to an RF frequency. The local oscillator must be tuned in an RF desired frequency band, and frequency resolution must be made equal to at least channel spacing.

A local oscillator for wireless communication differs in its use method depending on the block architecture of transmitting and receiving circuits. For example, a direct downconversion system in which an IF frequency is a zero frequency, a low IF system in which an IF frequency is a few MHz or so, and a heterodyne system have been adopted in a receiving circuit of an RFIC for a cellular phone. The local oscillators for these systems are configured as part of a frequency synthesizer for generating local signals. A heterodyne system or a direct upconversion system is adopted in a transmitting circuit of the RFIC for the cellular phone. Each local oscillator for these systems might also be configured as a modulator of a frequency synthesizer for generating local signals.

The local oscillator (LO) used for transmission and reception of an RF transceiver needs to have the function of fine adjusting or tuning the frequency of each local signal (LO) in a predetermined adjustment or control range. As described in the non-patent 2, the frequency tuning of the local signal (LO) comprises frequency tuning of the acquisition bank used for channel selection and frequency tuning of the tracking bank for transmission and reception. Since the acquisition bank is large in minimum frequency shift width, the acquisition bank assumes frequency coarse tuning. On the other hand, since the tracking bank for the transmission and reception is small in minimum frequency shift width, the tracking bank assumes frequency fine tuning.

For example, a range of frequency fine tuning used in follow-up itself of transmission and reception becomes an approximately 1% in a temperature range from −30° to +120° in general. On the other hand, a range of frequency coarse tuning used in acquisition itself used for channel selection differs depending on the system and specs for wireless communication. On the other hand, since the frequency coarse tuning based on the acquisition and the frequency fine tuning based on the follow-up are carried out between the actual transmission and reception, the range of frequency fine tuning also comprises the range of frequency coarse tuning.

For example, a cellular phone of a GSM system that uses a relatively low RF frequency band of an approximately 0.8 GHz needs a range of frequency fine tuning for acquisition of a several hundreds of kHz. A cellular phone of a WCDMA system that uses a relatively high RF frequency band of an approximately 2 GHz needs a range of frequency fine tuning for acquisition of a few tens of MHz.

Namely, when the range of frequency fine tuning for acquisition used for the channel selection is large like a few MHz or more as in the cellular phone of the WCDMA system, it has been revealed that linearity of digital signal to frequency conversion is degraded. As described in the non-patent document 2, the degradation of the linearity of the digital signal to frequency conversion results from errors of capacitances of each tracking bank per unit weight depending on an IC's manufacturing process. Thus, as described in the non-patent document 2, the linearity of the digital signal to frequency conversion due to the errors of the capacitances of the tracking bank can be improved by adopting a dynamic element matching (DEM) method This DEM method, however, needs to individually control the respective variable capacitors that configures the tracking bank. When the DEM method is applied to a tracking bank including a large number of variable capacitors like 2000, 4000 or the like for that purpose, control logic circuits for controlling the respective capacitors are also required individually as well as the need for 2000 or 4000 control lines. Therefore, a problem that a chip occupied area becomes large has been manifested by the present inventors et al.

It has been revealed by the discussions of the present inventors et al. that the degradation of the linearity of the digital signal to frequency conversion results from variations in control gain (K_{DCO}(Hz/bit) of a digitally controlled oscillator (DCO) due to changes in parasitic inductance when each capacitance value of the tracking bank is changed in response to a digital signal. A mechanism thereof will be explained hereinafter.

FIG. 36 is a schematic diagram showing a configuration of a voltage controlled oscillator (VCO) discussed by the present inventors et al. based on the description of the non-patent document 1 prior to the present invention. Namely, the voltage controlled oscillator (VCO) shown in FIG. 36 is one in which varactors CFA1 and CFA2 supplied with an analog tuning control voltage VCNT as capacitors of a tracking bank for frequency fine tuning are used in parallel with inductors L1 and L2 as an LC tank circuit having cross-coupled transistors NM1 and NM2.

FIG. 38 is a diagram showing frequency control characteristics of the voltage controlled oscillator (VCO) shown in FIG. 36. As shown in FIG. 38, an oscillation frequency can be changed continuously by changing the analog tuning control voltage V_{CNT}. In order to expand a control range for frequency fine tuning, the varactors CFA1 and CFA2 large in the amount of change in capacitance value are used or the width of change in the analog tuning control voltage VCNT may be set large. In the voltage controlled oscillator (VCO) shown in FIG. 36, however, the oscillation frequency and oscillation phase vary due to noise of the analog tuning control voltage VCNT. Therefore, a problem occurs in phase noise characteristic as described in the non-patent document 1.

FIG. 37 is a diagram showing a configuration of a digitally controlled oscillator (DCO) discussed by the present inventors et al. based on the description of the non-patent document 1 prior to the present invention. The digitally controlled oscillator (DCO) shown in FIG. 37 is one wherein varactors supplied with digital tuning control signals as capacitors of a tracking bank for frequency fine tuning are used in parallel with inductors L1 and L2 as an LC tank circuit having cross-coupled transistors NM1 and NM2.

FIG. 39 is a diagram illustrating frequency control characteristics of the digitally controlled oscillator (DCO) shown in FIG. 37. As shown in FIG. 37, the oscillation frequency can be changed stepwise as indicted by a solid line of FIG. 39 by on/off control of a matrix switch of a varactor array in the tracking bank by the digital tuning control signals. In order to expand a control range for frequency fine tuning, there is a need to use the varactor array large in the amount of change in capacitance value or increase the number of bits of each digital tuning control signal. It has been revealed that the latter method causes the problem that since an increase in the number of capacitors in the varactor array of the tracking bank occurs, the chip occupied area of the varactor array in the tracking bank increases. It has been revealed that as a result of discussions of the former method by the present inventors et al., the following problems occur.

That is, when the varactor array large in the amount of change in capacitance value is used, the amount of change in oscillation frequency due to a large capacitance change of one variable capacitor, i.e., a variation in control gain K_{DCO} of the digitally controlled oscillator (DCO) becomes excessively large. That is, it has been revealed by the discussions of the present inventors et al. that a problem arises in that since the amount of change in frequency corresponding to a step of FIG. 39 indicative of the frequency control characteristics of the digitally controlled oscillator (DCO) shown in FIG. 39 becomes large, the amount of degradation of phase noise due to quantization noise becomes large as well as degradation in the resolution of the oscillation frequency.

FIG. 40 is a diagram showing a simulation result of phase noise characteristics of an all digital PLL (AD-PLL) having adopted a digitally controlled oscillator (DCO) discussed by the present inventors et al. prior to the present invention. Incidentally, an oscillation frequency of the digitally controlled oscillator (DCO) was set to 2 GHz, whereas a loop bandwidth of the AD-PLL was set to 80 kHz.

It is understood from FIG. 40 that as the control gain K_{DCO} of the digitally controlled oscillator (DCO) is made larger, the degradation in phase noise due to the quantization noise becomes larger. As described in the non-patent documents 1 and 2, the method of adopting the ΣΔ modulator is provided to reduce the degradation in the phase noise. The adoption of the ΣΔ modulator, however, also causes a problem about increases in chip occupied area and power consumption as well as the growing complexity of design of the all digital PLL (AD-PLL).

Reversely, when a method for reducing the control gain K_{DCO} to the extent that the phase noise or quantization noise does not cause a problem and increasing the number of bits of each digital tuning control signal is adopted, it has been revealed by the discussions of the present inventors et al. that variations in the control gain K_{DCO} become a problem this time. Namely, since the control gain K_{DCO} is excessively reduced, the value itself of the control gain K_{DCO} varies, thus resulting in such a frequency control characteristic as indicated by a dotted line in FIG. 39. Thus, a problem arises in that due to discontinuity of the oscillation frequency control characteristic, spurious of a reference clock signal frequency produced in an output signal of all digital PLL (AD-PLL) increases and a phase error increases. A first cause of the variations in the control gain K_{DCO} is relative variations in variable capacitors that configure a variable capacitor array. There are considered, as the variable capacitors, a variable capacitor of a MOS varactor, a configuration using a fixed capacitor such as a MIM capacitor, and a switch, a pn-junction capacitance as a variable capacitor, etc. In any case, the amount of change in capacitance value of each variable capacitor that configures a capacitor array varies depending on relative variations in MOS transistor or the like, thereby resulting in variations in the control gain K_{DCO}.

It has been revealed by the discussions of the present inventors et al. that a second cause of the variations in the control gain K_{DCO} is attributed to parasitic inductance of each of wires for the variable capacitors.

FIG. 41 is a diagram showing a configuration of a varactor array discussed by the present inventors et al. prior to the present invention as the tracking bank of the digitally controlled oscillator (DCO) shown in FIG. 37. The varactor array shown in FIG. 41 is of a tracking bank small in minimum frequency shift width for transmission and reception. Capacitors per unit weight are arranged eight in the vertical direction and arranged eight in the horizontal direction, respectively. In the tracking bank, the use or non-use of each capacitor is determined by on/off of each switch in a switch matrix.

In a state prior to switching by each digital tuning control signal, one capacitor used in the tracking bank is assumed to be a capacitor Cnear located in a point A shortest to an RF signal input node. Since the influence of the parasitic inductance can be ignored at the point A shortest to the RF signal input node, input impedance ZA (near) at the point A can be described as follows:

$${Z}_{A} ( near ) = \frac{1}{jω C} \qquad ( 1 )$$

On the other hand, one capacitor used in the tracking bank is assumed to be changed from the capacitor Cnear located at the point A shortest to the RF signal input node from a capacitor Cfar located at point longest to the RF signal input node in a state after switching by the corresponding digital tuning control signal. Since the influence of a parasitic inductance L should be taken into consideration at the point longest to the RF signal input node, input impedance ZA (far) at the point A can be described in the following manner because the capacitance C and parasitic inductance L are provided in series:

$${Z}_{A} ( far ) = \frac{1 - {ω}^{2} LC}{jω C} \qquad ( 2 )$$

Thus, the larger the parasitic inductance L based on the wire, the larger the difference between the input impedances Z_{A} calculated in the equations (1) and (2), so that dependence on a change in frequency also becomes large. With such a mechanism, the control gain K_{DCO} of the digitally controlled oscillator (DCO) is considered to vary when the position of each capacitor used in the tracking bank changes depending on a change in digital tuning control signal.

FIG. 42 is also a diagram showing a configuration of a varactor array driven by an RF differential input signal, which has been discussed by the present inventors et al. prior to the present invention as the tracking bank of the digitally controlled oscillator (DCO) of FIG. 37. FIG. 42 is different from FIG. 41 in that the respective capacitors of the tracking bank are driven by RF differential input signals supplied to differential input terminals B and C. Similarly to FIG. 41, the varactor array shown in FIG. 42 also corresponds to a tracking bank small in minimum frequency shift width for transmission and reception. Capacitors per unit weight are arranged eight in the vertical direction and arranged eight in the horizontal direction respectively. In the tracking bank, the use/non-use of the capacitors is determined depending on on/off of switches in a switch matrix. A parasitic inductance L of a wire for one input terminal B and a parasitic inductance L of a wire for the other input terminal C are coupled to the capacitors of the varactor array shown in FIG. 42.

FIG. 43 is a diagram showing a simplified equivalent circuit for examining a change in impedance due to a change in the position of each capacitor used depending on a change in each digital tuning control signal in the varactor array shown in FIG. 42.

In the equivalent circuit shown in FIG. 43, the input impedance at the differential input terminals B and C where all of three capacitors C₁, C₂ and C₃ are used, can be calculated as follows:

$${Z}_{BC 123} = iω L + \frac{1}{2 jω C} - \frac{1}{4 jω C ( 1 - {ω}^{2} LC )} \qquad ( 3 )$$

Next, in the equivalent circuit shown in FIG. 43, the input impedance at the differential input terminals B and C where the capacitor C₂ placed in the center of the three capacitors C₁, C₂ and C₃ is not used and the right and left capacitors C₁ and C₃ are used, can be calculated as follows:

$${Z}_{BC 13} = \frac{1 + {ω}^{2} LC}{2 jω C} \qquad ( 4 )$$

Next, in the equivalent circuit shown in FIG. 43, the input impedance at the differential input terminals B and C where the capacitor C₂ placed in the center of the three capacitors C₁, C₂ and C₃ and the right capacitor C₃ are not used, and only the left capacitor C₁ is used, can be calculated as follows:

$${Z}_{BC 2} = \frac{1 - 2 {ω}^{2} LC}{2 jω C} \qquad ( 5 )$$

Thus, the larger the parasitic inductance L based on the wire, the larger the difference between the input impedances calculated in the equations (3), (4) and (5), so that dependence on a change in frequency also increases. With such a mechanism, the control gain K_{DCO} Of the digitally controlled oscillator (DCO) is considered to vary when the position of each capacitor used in the tracking bank changes depending on a change in digital tuning control signal.

As described above, the dynamic element matching (DEM) method can be adopted to reduce the variations in the control gain K_{DCO} of such a digitally controlled oscillator (DCO). The DEM method, however, needs to individually control the respective variable capacitors that configure the tracking bank. Thus, when the DEM method is applied to a tracking bank containing a large number of variable capacitors, say 2000, 4000 or the like, a problem that since control logic circuits for controlling individual capacitors are also required individually as well as the need for control lines of 2000 or 4000, a chip occupied area increases, has been manifested by the present inventors et al.

The present invention has been made as a result of the discussions of the present inventors et al. prior to the present invention such as described above.

Thus, an object of the present invention is to provide a semiconductor integrated circuit capable of reducing a chip occupied area and reducing variations in control gain K_{DCO} of a digitally controlled oscillator (DCO).

The above and other objects and novel features of the present invention will become apparent from the description of the present specification and the accompanying drawings.

A typical one of the inventions disclosed in the present application will be explained in brief as follows:

A typical semiconductor integrated circuit of the present invention comprises a digitally controlled oscillator (DCO).

The digitally controlled oscillator comprises oscillation transistors (NM1 and NM2) and a resonant circuit (10). The resonant circuit (10) comprises inductances (L11 and L12), a frequency coarse-tuning variable capacitor array (CCT11) and a frequency fine-tuning variable capacitor array (CFT11).

The frequency coarse-tuning variable capacitor array (CCT11) comprises a plurality of coarse-tuning capacitor unit cells (CCT<0>, CCT<1> . . . ) respectively controlled by coarse-tuning digital control signals (VCT<0>, VCT<1> . . . ). The frequency fine-tuning variable capacitor array (CFT11) comprises a plurality of fine-tuning capacitor unit cells (CFT<0>, CFT<1> . . . ) respectively controlled by fine-tuning digital control signals (VFT<0>, VFT<1> . . . ).

The capacitance values of the coarse-tuning capacitor unit cells of the frequency coarse-tuning variable capacitor array (CCT11) are set in accordance with a binary weight (2^{M-1}). The capacitance values of the fine-tuning capacitor unit cells of the frequency fine-tuning variable capacitor array (CFT11) are set in accordance with a binary weight (2^{N-1}) (see FIG. 1).

An advantageous effect obtained by a typical one of the inventions disclosed in the present application will be explained in brief as follows:

There can be provided a semiconductor integrated circuit capable of reducing a chip occupied area and reducing variations in control gain K_{DCO} of a digitally controlled oscillator (DCO).

### BRIEF DESCRIPTION OF THE DRAWINGS

FIG. 1 is a diagram showing a configuration of a digitally controlled oscillator mounted in a semiconductor integrated circuit according to an embodiment of the present invention and suitable to reduce variations in control gain thereof;

FIG. 2 is a diagram illustrating a configuration of a symmetrically-arranged digitally controlled oscillator mounted in a semiconductor integrated circuit according to another embodiment of the present invention and suitable to reduce variations in control gain thereof;

FIG. 3 is a diagram depicting the manner in which first and second arrays of a frequency fine-tuning variable capacitor array of the digitally controlled oscillator shown in FIG. 2 are arranged symmetrically over a semiconductor chip of the semiconductor integrated circuit;

FIG. 4 is a diagram showing a configuration of a digitally controlled oscillator mounted in a semiconductor integrated circuit according to a further embodiment of the present invention and having branch signal wires suitable to reduce variations in control gain thereof;

FIG. 5 is a diagram illustrating a simplified equivalent circuit for examining changes in impedance due to changes in positions of capacitors used in a frequency fine-tuning variable capacitor array of the digitally controlled oscillator shown in FIG. 4 depending on changes in digital tuning control signals;

FIG. 6 is a diagram showing a configuration of a digitally controlled oscillator mounted in a semiconductor integrated circuit according to a still further embodiment of the present invention and having branch signal wires in a symmetric arrangement suitable to reduce variations in control gain thereof;

FIG. 7 is a diagram depicting a configuration of a digitally controlled oscillator mounted in a semiconductor integrated circuit according to a still further embodiment of the present invention and suitable to reduce variations in control gain thereof;

FIG. 8 is a diagram showing a configuration of a digitally controlled oscillator mounted in a semiconductor integrated circuit according to a still further embodiment of the present invention and suitable to reduce variations in control gain thereof;

FIG. 9 is a diagram illustrating a configuration of a digitally controlled oscillator mounted in a semiconductor integrated circuit according to a still further embodiment of the present invention and suitable to reduce variations in control gain thereof;

FIG. 10 is a diagram depicting a configuration of a symmetrically-arranged digitally controlled oscillator mounted in a semiconductor integrated circuit according to a still further embodiment of the present invention and suitable to reduce variations in control gain thereof and reduce phase noise;

FIG. 11 is a diagram showing the manner in which sub capacitor arrays of the digitally controlled oscillator according to the still further embodiment of the present invention shown in FIG. 7 are laid out in the semiconductor integrated circuit;

FIG. 12 is a diagram showing a configuration of each of capacitor unit cells respectively usable as M capacitor unit cells of a frequency coarse-tuning variable capacitor array of a resonant circuit of the digitally controlled oscillator according to the embodiment of the present invention shown in FIG. 1 and N capacitor unit cells of a frequency fine-tuning variable capacitor array thereof;

FIG. 13 is a diagram illustrating another configuration of each of capacitor unit cells respectively usable as the M capacitor unit cells of the frequency coarse-tuning variable capacitor array of the resonant circuit of the digitally controlled oscillator according to the embodiment of the present invention shown in FIG. 1 and the N capacitor unit cells of the frequency fine-tuning variable capacitor array thereof;

FIG. 14 is a diagram showing a further configuration of each of capacitor unit cells respectively usable as the M capacitor unit cells of the frequency coarse-tuning variable capacitor array of the resonant circuit of the digitally controlled oscillator according to the embodiment of the present invention shown in FIG. 1 and the N capacitor unit cells of the frequency fine-tuning variable capacitor array thereof;

FIG. 15 is a diagram illustrating the structure of a capacitor of each of the capacitor unit cells shown in FIGS. 12 through 14;

FIG. 16 is a diagram showing a configuration of a chip layout of a semiconductor integrated circuit for setting capacitance values of the capacitor unit cells of the frequency fine-tuning variable capacitor array of the resonant circuit of the digitally controlled oscillator according to the embodiment of the present invention shown in FIG. 1 in accordance with a rule of binary weight 2^{N-1};

FIG. 17 is a diagram for describing the conditions of use of plural capacitor unit cells where the number of control codes of digital tuning control signals is 15 in a system based on capacitance values per unit weight of the capacitor unit cells of the frequency fine-tuning variable capacitor array used in the tracking bank of the digitally controlled oscillator shown in FIG. 1;

FIG. 18 is a diagram for describing the conditions of use of plural capacitor unit cells where the number of control codes of digital tuning control signals is 16 in the system based on the capacitance values per unit weight of the capacitor unit cells of the frequency fine-tuning variable capacitor array used in the tracking bank of the digitally controlled oscillator shown in FIG. 1;

FIG. 19 is a diagram for describing the conditions of use of capacitor unit cells where the number of control codes of digital tuning control signals is 15 in sub capacitor arrays of the digitally controlled oscillator according to the still further embodiment of the present invention shown in FIG. 7;

FIG. 20 is a diagram for describing the conditions of use of capacitor unit cells where the number of control codes of digital tuning control signals is 16 in the sub capacitor arrays of the digitally controlled oscillator according to the still further embodiment of the present invention shown in FIG. 7;

FIG. 21 is a diagram showing a configuration of sub capacitor arrays of the frequency fine-tuning variable capacitor array, which have been improved in consideration of its use in an all digital PLL of the digitally controlled oscillator according to the embodiment shown in FIG. 7;

FIG. 22 is a diagram illustrating the effect of reducing variations in control gain by array division or sub capacitor array division of each of the frequency fine-tuning variable capacitor arrays of the digitally controlled oscillators according to the various embodiments of the present invention;

FIG. 23 is a diagram showing the effect of reducing variations in control gain by array division or sub capacitor array division of each of the frequency fine-tuning variable capacitor arrays of the digitally controlled oscillators according to the various embodiments of the present invention in a manner similar to FIG. 22;

FIG. 24 is a diagram showing the effect of reducing variations in control gain by the frequency fine-tuning variable capacitor arrays of the digitally controlled oscillators according to the embodiments of the present invention being divided into plural form and taken as branch signal wires as shown in FIGS. 6 and 9;

FIG. 25 is a diagram showing a configuration of a digital PLL mounted in a semiconductor integrated circuit according to another embodiment of the present invention and including a digitally controlled oscillator in which variations in control gain thereof have been reduced;

FIG. 26 is a diagram showing a configuration of a digital PLL mounted in a semiconductor integrated circuit according to a further embodiment of the present invention and including a digitally controlled oscillator in which variations in control gain thereof have been reduced;

FIG. 27 is a diagram showing a configuration of a digital PLL mounted in a semiconductor integrated circuit according to a still further embodiment of the present invention and including a digitally controlled oscillator in which variations in control gain thereof have been reduced;

FIG. 28 is a diagram showing a configuration of a digital PLL mounted in a semiconductor integrated circuit according to a still further embodiment of the present invention and including a digitally controlled oscillator in which variations in control gain thereof have been reduced;

FIG. 29 is a diagram illustrating a configuration of a digital PLL mounted in a semiconductor integrated circuit according to a still further embodiment of the present invention and including a digitally controlled oscillator in which variations in control gain thereof have been reduced;

FIG. 30 is a diagram depicting a configuration of a wireless receiver mounted in a semiconductor integrated circuit according to a still further embodiment of the present invention and including a digitally controlled oscillator or a digital PLL in which variations in control gain thereof have been reduced;

FIG. 31 is a diagram showing a configuration of a wireless receiver mounted in a semiconductor integrated circuit according to a still further embodiment of the present invention and including a digitally controlled oscillator or a digital PLL in which variations in control gain thereof have been reduced;

FIG. 32 is a diagram illustrating a configuration of a wireless receiver mounted in a semiconductor integrated circuit according to a still further embodiment of the present invention and including a digitally controlled oscillator or a digital PLL in which variations in control gain thereof have been reduced;

FIG. 33 is a diagram depicting a configuration of a wireless transceiver mounted in a semiconductor integrated circuit according to a still further embodiment of the present invention and including a digitally controlled oscillator or a digital PLL in which variations in control gain thereof have been reduced;

FIG. 34 is a diagram showing a configuration of a wireless transceiver mounted in a semiconductor integrated circuit according to a still further embodiment of the present invention and including a digitally controlled oscillator or a digital PLL in which variations in control gain thereof have been reduced;

FIG. 35 is a diagram illustrating a configuration of a wireless transceiver mounted in a semiconductor integrated circuit according to a still further embodiment of the present invention and including a digitally controlled oscillator or a digital PLL in which variations in control gain thereof have been reduced;

FIG. 36 is a diagram showing a configuration of a voltage controlled oscillator discussed by the present inventors et al. based on the description of the non-patent document 1 prior to the present invention;

FIG. 37 is a diagram depicting a configuration of a digitally controlled oscillator discussed by the present inventors et al. based on the description of the non-patent document 1 prior to the present invention;

FIG. 38 is a diagram showing frequency control characteristics of the voltage controlled oscillator shown in FIG. 36;

FIG. 39 is a diagram illustrating frequency control characteristics of the digitally controlled oscillator shown in FIG. 37;

FIG. 40 is a diagram depicting a simulation result of phase noise characteristics of an all digital PLL (AD-PLL) having adopted a digitally controlled oscillator discussed by the present inventors et al. prior to the present invention;

FIG. 41 is a diagram showing a configuration of a varactor array discussed by the present inventors et al. prior to the present invention as the tracking bank of the digitally controlled oscillator shown in FIG. 37;

FIG. 42 is a diagram illustrating a configuration of a varactor array driven by an RF differential input signal, which has been discussed by the present inventors et al. prior to the present invention as the tracking bank of the digitally controlled oscillator shown in FIG. 37; and

FIG. 43 is a diagram showing a simplified equivalent circuit for examining a change in impedance due to a change in the position of each capacitor used depending on a change in a digital tuning control signal in the varactor array shown in FIG. 42.

### DETAILED DESCRIPTION OF THE PREFFERED EMBODIMENTS

### Summary of a Typical Embodiment

A summary of a typical embodiment of the inventions disclosed in the present application will first be explained. Reference numerals in the accompanying figures referred to with parentheses applied thereto in the description of the summary of the typical embodiment are merely illustrations of those contained in the concepts of components marked with the reference numerals.

[1] A semiconductor integrated circuit according to a typical embodiment of the present invention comprises a digitally controlled oscillator (DCO).

The digitally controlled oscillator comprises oscillation transistors (NM1 and NM2) and a resonant circuit (10).

The resonant circuit (10) comprises inductances (L11 and L12), a frequency coarse-tuning variable capacitor array (CCT11) and a frequency fine-tuning variable capacitor array (CFT11).

The frequency coarse-tuning variable capacitor array (CCT11) at least comprises a plurality of coarse-tuning capacitor unit cells (CCT<0>, CCT<1> . . . CCT<M−1>) corresponding to a first predetermined number (M), which are respectively controlled by coarse-tuning digital control signals (VCT<0>, VCT<1> . . . VCT<M−1>) having the number of bits corresponding to the first predetermined number (M).

The frequency fine-tuning variable capacitor array (CFT11) at least comprises a plurality of fine-tuning capacitor unit cells (CFT<0>, CFT<1> . . . CFT<N−1>) corresponding to a second predetermined number (N), which are respectively controlled by fine-tuning digital control signals (VFT<0>, VFT<1> . . . VFT<N−1>) having the number of bits corresponding to the second predetermined number (N).

Capacitance values of the coarse-tuning capacitor unit cells (CCT<0>, CCT<1> . . . CCT<M−1>) of the frequency coarse-tuning variable capacitor array (CCT11) are set in accordance with a binary weight (2^{M-1}).

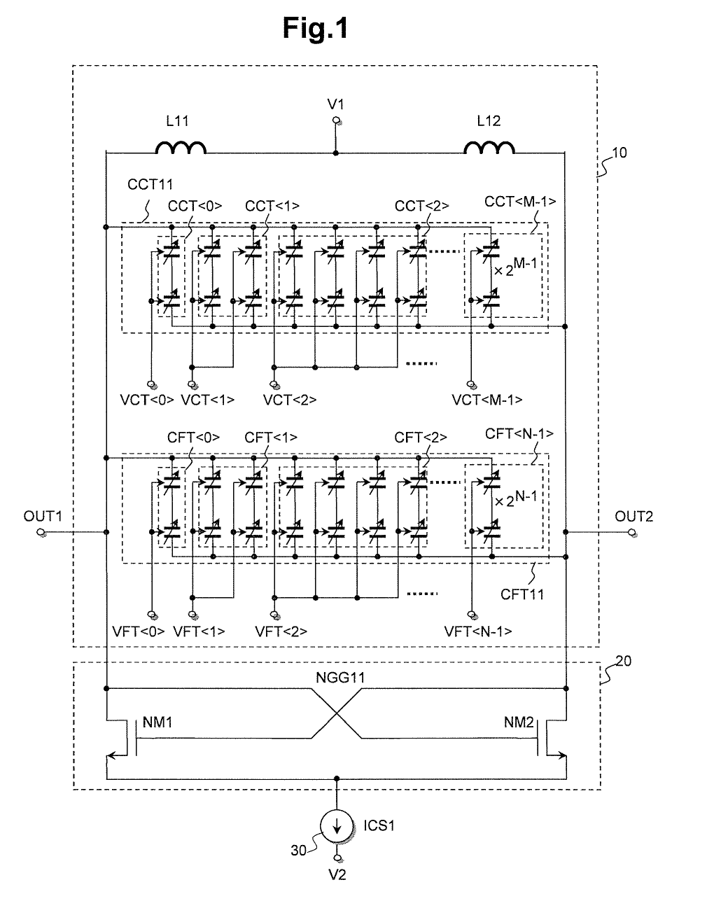

Capacitance values of the fine-tuning capacitor unit cells (CFT<0>, CFT<1> . . . CFT<N−1>) of the frequency fine-tuning variable capacitor array (CFT11) are set in accordance with a binary weight (2^{N-1}) (see FIG. 1).

According to the embodiment, although the capacitance values of the fine-tuning capacitor unit cells (CFT<0>, CFT<1> . . . CFT<N−1>) of the frequency fine-tuning variable capacitor array (CFT11) have conventionally been set to the capacitance values per unit weight, variations in control gain K_{DCO} of the digitally controlled oscillator (DCO) can be reduced because they have been set in accordance with the binary weight (2^{N-1}).

According to a preferred embodiment, the minimum frequency transition width of the frequency fine-tuning variable capacitor array (CFT11) is set smaller than that of the frequency coarse-tuning variable capacitor array (CCT11) (see FIG. 1).

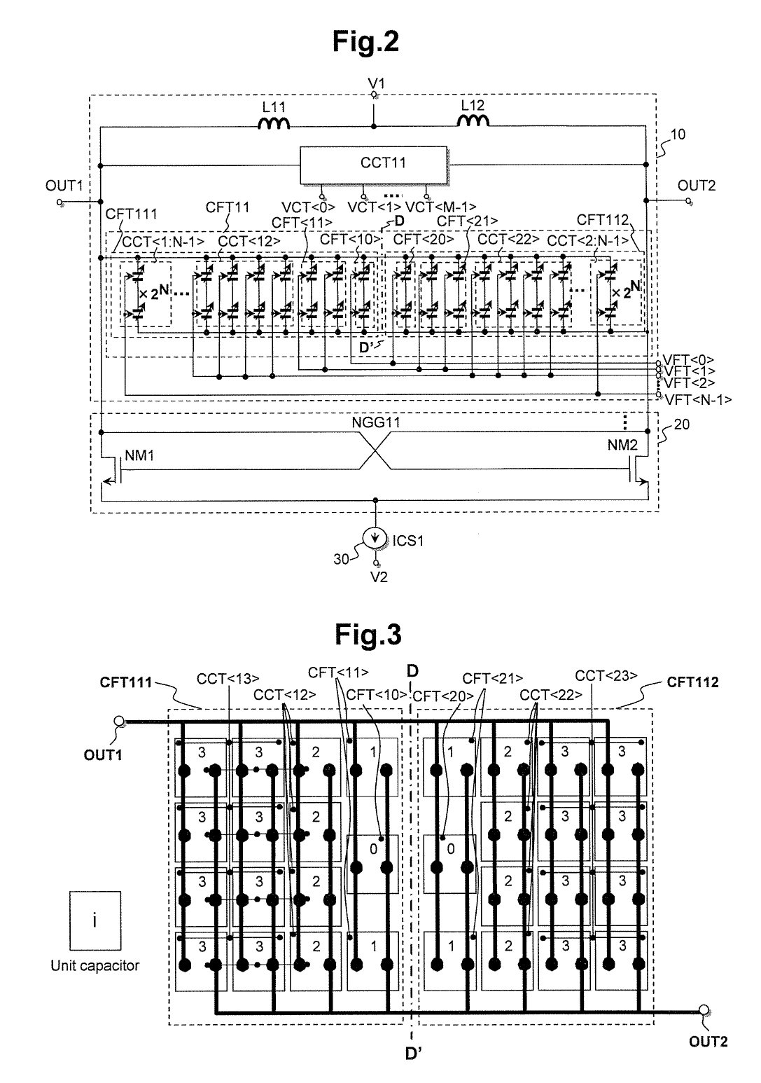

According to another preferred embodiment, the frequency fine-tuning variable capacitor array (CFT11) comprises a plurality of capacitor arrays (CFT111 and CFT112) respectively controlled by the fine-tuning digital control signals (VFT<0>, VFT<1> . . . VFT<N−1>) (see FIG. 2).

According to a more preferred embodiment, the capacitor arrays (CFT111 and CFT112) are arranged symmetrically about a center line (DD′) (see FIG. 2). According to a still more preferred embodiment, the fine-tuning capacitor unit cells (CFT<0>, CFT<1> . . . CFT<N−1>) of the frequency fine-tuning variable capacitor array (CFT11) are respectively comprised of unit capacitors corresponding to the number of pieces set in accordance with a binary weight (2^{N-1}). The unit capacitors respectively have capacitance areas identical to one another (see FIG. 3).

According to a still more preferred embodiment, the oscillation transistors at least comprise a first transistor (NM1) and a second transistor (NM2), and the inductances at least comprise a first inductance (L11) and a second inductance (L12).

An output electrode of the first transistor (NM1) and a control input electrode of the second transistor (NM2) are coupled to one end (OUT1) of the first inductance (L11), whereas an output electrode of the second transistor (NM2) and a control input electrode of the first transistor (NM1) are coupled to one end (OUT2) of the second inductance (L12).

The other end of the first inductance (L1) and the other end of the second inductance (L12) are coupled to an operating potential point (V1).

The frequency coarse-tuning variable capacitor array (CCT11) and the frequency fine-tuning variable capacitor array (CFT11) are coupled in parallel between the one end (OUT1) of the first inductance (L11) and the one end (OUT2) of the second inductance (L12) (see FIG. 1).

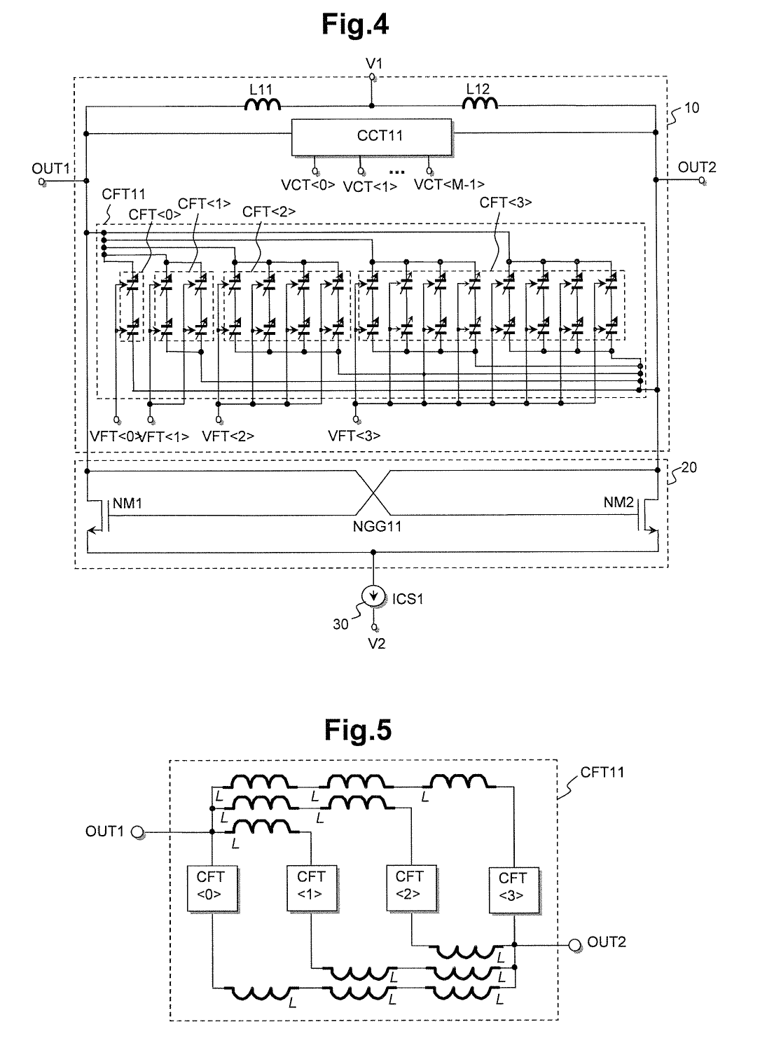

According to one concrete embodiment, one ends of unit cells of the fine-tuning capacitor unit cells (CFT<0>, CFT<1> . . . CFT<N−1>) of the frequency fine-tuning variable capacitor array (CFT11) are respectively coupled to the one end (OUT1) of the first inductance (L11) through independent first branch signal wires. The other ends of the unit cells of the fine-tuning capacitor unit cells (CFT<0>, CFT<1> . . . CFT<N−1>) of the frequency fine-tuning variable capacitor array (CFT11) are respectively coupled to the one end (OUT2) of the second inductance (L12) through independent second branch signal wires (see FIG. 4).

According to another concrete embodiment, unit cells of the coarse-tuning capacitor unit cells of the frequency coarse-tuning variable capacitor array (CCT11) and unit cells of the fine-tuning capacitor unit cells of the frequency fine-tuning variable capacitor array (CFT11) are respectively comprised of first capacitors (CF1XP) whose one ends are coupled to the one end (OUT1) of the first inductance (L11, second capacitors (CF1XN) whose one ends are coupled to the one end (OUT2) of the second inductance (L12), and switching transistors (NMSW) each coupled between the other end of the first capacitor (CF1XP) and the other end of the second capacitor (CF1XN) (see FIGS. 12, 13 and 14).

According to a further concrete embodiment, the digitally controlled oscillator (DCO) is included in a digital PLL including a phase frequency detector (201), a digital loop filter (203) and a divider (200). An oscillation frequency of the digitally controlled oscillator (DCO) is controlled by the output of the digital loop filter (203) (see FIGS. 25, 26, 27, 28 and 29).

In a most concrete embodiment, the semiconductor integrated circuit comprises at least either one of a receiver for receiving an RF receive signal therein and generating a reception baseband signal by frequency downconversion, and a transmitter for generating an RF transmit signal by frequency upconversion of a transmission baseband signal.

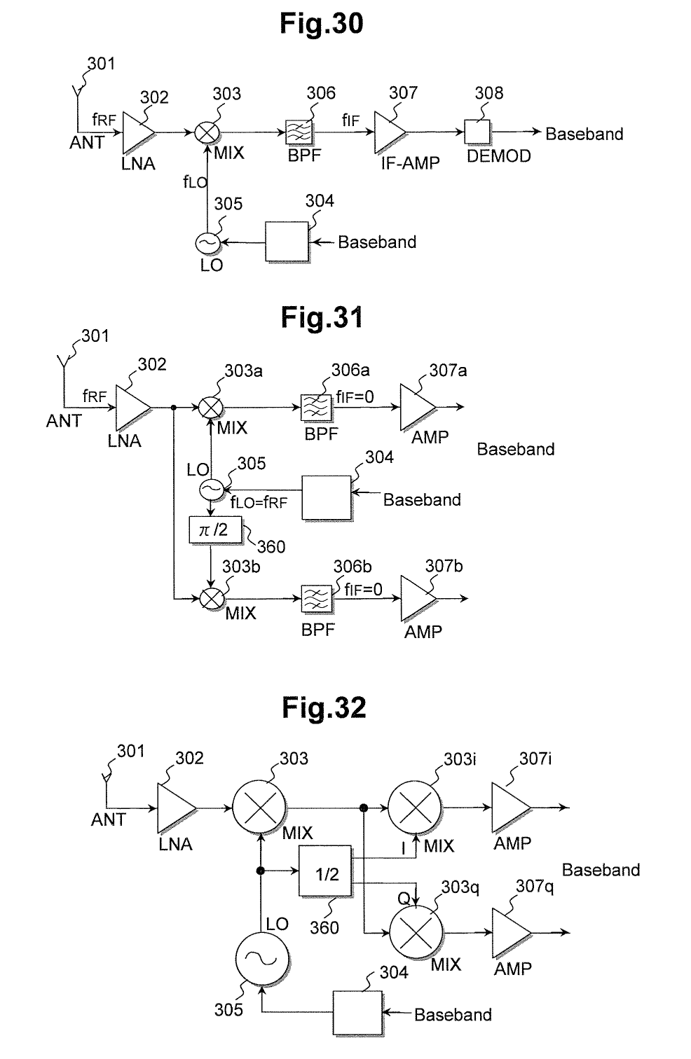

The digital PLL is operated as a frequency synthesizer for generating at least either one of a reception local signal based on the frequency downconversion of the receiver and a transmission local signal based on the frequency upconversion of the transmitter (see FIGS. 30, 31, 32, 33, 34 and 35).

[2] A semiconductor integrated circuit according to a typical embodiment of another aspect of the present invention is equipped with a digitally controlled oscillator (DCO).

The digitally controlled oscillator comprises oscillation transistors (NM1 and NM2) and a resonant circuit (20).

The resonant circuit (20) comprises inductances (L11 and L12), a channel selection acquiring variable capacitor array (CCT11) and a follow-up tuning variable capacitor array (CFT11).

The channel selection acquiring variable capacitor array (CCT11) at least comprises a plurality of channel selection acquiring capacitor unit cells (CCT<0>, CCT<1> . . . CCT<M−1>) corresponding to a first predetermined number (M), which are respectively controlled by channel selection acquisition digital control signals (VCT<0>, VCT<1> . . . VCT<M−1>) having the number of bits corresponding to the first predetermined number (M).

The follow-up tuning variable capacitor array (CFT11) at least comprises a plurality of follow-up tuning capacitor unit cells (CFT<0>, CFT<1> . . . CFT<N−1>) corresponding to a second predetermined number (N), which are respectively controlled by follow-up tuning digital control signals (VFT<0>, VFT<1> . . . VFT<N−1>) having the number of bits corresponding to the second predetermined number (N).

Capacitance values of the channel selection acquiring capacitor unit cells (CCT<0>, CCT<1> . . . CCT<M−1>) of the channel selection acquiring variable capacitor array (CCT11) are set in accordance with a binary weight (2^{M-1}).

Capacitance values of the follow-up tuning capacitor unit cells (CFT<0>, CFT<1> . . . CFT<N−1>) of the follow-up tuning variable capacitor array (CFT11) are set in accordance with a binary weight (2^{N-1}) (see FIG. 1).

According to the embodiment, although the capacitance values of the follow-up tuning capacitor unit cells (CFT<0>, CFT<1> . . . CFT<N−1>) of the follow-up tuning variable capacitor array (CFT11) have conventionally been set to the capacitance values per unit weight, variations in control gain K_{DCO} of the digitally controlled oscillator (DCO) can be reduced because they have been set in accordance with the binary weight (2^{N-1}).

According to a preferred embodiment, the minimum frequency transition width of the follow-up tuning variable capacitor array (CFT11) is set smaller than that of the channel selection acquiring variable capacitor array (CCT11) (see FIG. 1).

According to another preferred embodiment, the follow-up tuning variable capacitor array (CFT11) comprises a plurality of capacitor arrays (CFT111 and CFT112) respectively controlled by the follow-up tuning digital control signals (VFT<0>, VFT<1> . . . VFT<N−1>) (see FIG. 2).

According to a more preferred embodiment, the capacitor arrays (CFT111 and CFT112) are arranged symmetrically about a center line (DD′) (see FIG. 2).

According to still another preferred embodiment, the follow-up tuning capacitor unit cells (CFT<0>, CFT<1> . . . CFT<N−1>) of the follow-up tuning variable capacitor array (CFT11) are respectively comprised of unit capacitors corresponding to the number of pieces set in accordance with a binary weight (2^{N-1}). The unit capacitors respectively have capacitance areas identical to one another (see FIG. 3).

According to a still more preferred embodiment, the oscillation transistors at least comprise a first transistor (NM1) and a second transistor (NM2), and the inductances at least comprise a first inductance (L11) and a second inductance (L12).

An output electrode of the first transistor (NM1) and a control input electrode of the second transistor (NM2) are coupled to one end (OUT1) of the first inductance (L11), whereas an output electrode of the second transistor (NM2) and a control input electrode of the first transistor (NM1) are coupled to one end (OUT2) of the second inductance (L12).

The other end of the first inductance (L11) and the other end of the second inductance (L12) are coupled to an operating potential point (V1.

The channel selection acquiring variable capacitor array (CCT11) and the follow-up tuning variable capacitor array (CFT11) are coupled in parallel between the one end (OUT1) of the first inductance (L11) and the one end (OUT2) of the second inductance (L12) (see FIG. 1).

According to one concrete embodiment, one ends of unit cells of the follow-up tuning capacitor unit cells (CFT<0>, CFT<1> . . . CFT<N−1>) of the follow-up tuning variable capacitor array (CFT11) are respectively coupled to the one end (OUT1) of the first inductance (L11) through independent first branch signal wires. The other ends of the unit cells of the follow-up tuning capacitor unit cells (CFT<0>, CFT<1> . . . CFT<N−1>) of the follow-up tuning variable capacitor array (CFT11) are respectively coupled to the one end (OUT2) of the second inductance (L12) through independent second branch signal wires (see FIG. 4).

According to another concrete embodiment, unit cells of the channel selection acquiring capacitor unit cells of the channel selection acquiring variable capacitor array (CCT11) and unit cells of the follow-up tuning capacitor unit cells of the follow-up tuning variable capacitor array (CFT11) are respectively comprised of first capacitors (CF1XP) whose one ends are coupled to the one end (OUT1) of the first inductance (L11), second capacitors (CF1XN) whose one ends are coupled to the one end (OUT2) of the second inductance (L12), and switching transistors (NMSW) each coupled between the other end of the first capacitor (CF1XP) and the other end of the second capacitor (CF1XN) (see FIGS. 12, 13 and 14).

According to a further concrete embodiment, the digitally controlled oscillator (DCO) is included in a digital PLL including a phase frequency detector (201), a digital loop filter (203) and a divider (200). An oscillation frequency of the digitally controlled oscillator (DCO) is controlled by the output of the digital loop filter (203) (see FIGS. 25, 26, 27, 28 and 29).

In a most concrete embodiment, the semiconductor integrated circuit comprises at least either one of a receiver for receiving an RF receive signal therein and generating a reception baseband signal by frequency downconversion, and a transmitter for generating an RF transmit signal by frequency upconversion of a transmission baseband signal.

The digital PLL is operated as a frequency synthesizer for generating at least either one of a reception local signal based on the frequency downconversion of the receiver and a transmission local signal based on the frequency upconversion of the transmitter (see FIGS. 30, 31, 32, 33, 34 and 35).

### Description of Embodiments

Embodiments will next be described in detail. In all drawings for describing the best modes for implementing the invention, components having the same functions as in the above drawings are respectively identified by like reference numerals, and their repetitive explanations will therefore be omitted.

### <<Digitally Controlled Oscillator>>

FIG. 1 is a diagram showing a configuration of a digitally controlled oscillator (DCO) mounted in a semiconductor integrated circuit according to an embodiment of the present invention and suitable to reduce variations in control gain K_{DCO} thereof.

The digitally controlled oscillator (DCO) according to the embodiment of the present invention shown in FIG. 1 comprises a resonant circuit 10, an ac current generator 20 and a current source circuit 30.

The current source circuit 30 determines a constant current I_{CS1} for operating the digitally controlled oscillator (DCO). The ac current generator 20 comprises cross-coupled transistors NM1 and NM2 for generating negative resistance for canceling out parasitic resistance components of an LC tank circuit of the resonance circuit 10 coupled between a first output terminal OUT1 and a second output terminal OUT1 and thereby performing oscillating operations. The resonant circuit 10 essentially comprises the LC tank circuit for oscillation, but, to explain it in further detail, comprises a frequency coarse tuning variable capacitor array CCT11 for frequency coarse tuning of an acquisition bank large in minimum frequency shift width and used for channel selection, and a frequency fine tuning variable capacitor array CFT11 for frequency fine tuning of a tracking bank small in minimum frequency shift width and used for transmission and reception as described in the non-patent document 2. Further, the resonant circuit 10 comprises inductors L11 and L12 formed as spiral inductors in the surface of a chip of the semiconductor integrated circuit.

### <<Frequency Coarse-Tuning Variable Capacitor Array>>

The frequency coarse-tuning variable capacitor array CCT11 used in the acquisition band for the channel selection comprises M capacitor unit cells CCT<0>, CCT<1> . . . CCT<M−1> respectively controlled by M-bit channel selection digital control signals VCT<0>, VCT<1> . . . VCT<M−1>.

In particular, the capacitance values of the capacitor unit cells CCT<0>, CCT<1> . . . CCT<M−1> of the frequency coarse-tuning variable capacitor array CCT11 for the acquisition bank are respectively determined in accordance with a rule of binary weight 2^{N-1}. Thus, the capacitance of the first capacitor unit cell CCT<0> is set to a capacitance value of CC×2⁰=1 CC, the capacitance of the second capacitor unit cell CCT<1> is set to a capacitance value of CC×2¹=2 CC, the capacitance of the third capacitor unit cell CCT<2> is set to a capacitance value of CC×2²=4 CC, the capacitance of the fourth capacitor unit cell CCT<3> is set to a capacitance value of CC×2³=8 CC, and the capacitance of the Mth capacitor unit cell CCT<M−1> is set to a capacitance value of CC×2^{M-1}. Since the minimum frequency shift width is set to a large value in the frequency coarse-tuning variable capacitor array CCT11 used in the acquisition bank for the channel selection, each unit capacitor CC is set to a relatively large value.

The use or nonuse of the capacitors included in the capacitor unit cells of the frequency coarse-tuning variable capacitor array CCT11 for the acquisition bank is determined depending on on/off of switches included in the capacitor unit cells. Further, the M capacitor unit cells CCT<0>, CCT<1> . . . CCT<M−1> of the frequency coarse-tuning variable capacitor array CCT11 for the acquisition bank can respectively be realized by a structure shown in FIG. 12, for example.

### <<Capacitor Unit Cell>>

FIG. 12 is a diagram showing a configuration of each of capacitor unit cells respectively usable as the M capacitor unit cells of the frequency coarse-tuning variable capacitor array CCT11 and the N capacitor unit cells of the frequency fine-tuning variable capacitor array CFT11 in the resonant circuit 10 of the digitally controlled oscillator (DCO) according to the embodiment of the present invention shown in FIG. 1.

As shown in FIG. 12, one capacitor unit cell essentially comprises two capacitors CF1XP and CF1XN and a switch transistor NMSW. A gate control input terminal of the switch transistor NMSW is controlled by a one-bit control signal BIT of a channel selection digital control signal. On the other hand, the first capacitor CF1XP, a drain-source current path of the switch transistor NMSW and the second capacitor CF1XN are coupled between a first output terminal OUT1 of the digitally controlled oscillator (DCO) and a second output terminal OUT2 thereof. A bias applying resistor RB1P is coupled between a drain SWD of the switch transistor NMSW and a ground voltage GND. A bias applying resistor RB1N is coupled between a source SWS of the switch transistor NMSW and the ground voltage GND.

The use or non-use of the two capacitors CF1XP and CF1XN of the capacitor unit cell is determined depending on on/off of the switch transistor NMSW. That is, since the switch transistor NMSW is of an N channel MOS transistor, the switch transistor NMSW is controlled to an on state by a one-bit control signal BIT of a high level “1”. In doing so, the first capacitor CF1XP and the second capacitor CF1XN are coupled in series between the first output terminal OUT1 of the digitally controlled oscillator (DCO) and the second output terminal OUT1 thereof. When the one-bit control signal BIT is brought to a low level “0”, the switch transistor NMSW is controlled to an off state, so that an open state is obtained between the first and second output terminals OUT1 and OUT2 of the digitally controlled oscillator (DCO).

FIG. 13 is a diagram showing another configuration of each of capacitor unit cells respectively usable as the M capacitor unit cells of the frequency coarse-tuning variable capacitor array CCT11 of the resonant circuit 10 of the digitally controlled oscillator (DCO) according to the embodiment of the present invention shown in FIG. 1 and the N capacitor unit cells of the frequency fine-tuning variable capacitor array CFT11 thereof.

In FIG. 13, the bias applying resistors RB1P and RB1N of the capacitor unit cell shown in FIG. 12 are replaced with bias N channel MOS transistors NMBP and NMBN. A bias voltage BIAS is applied to gates of the bias transistors NMBP and NMBN.

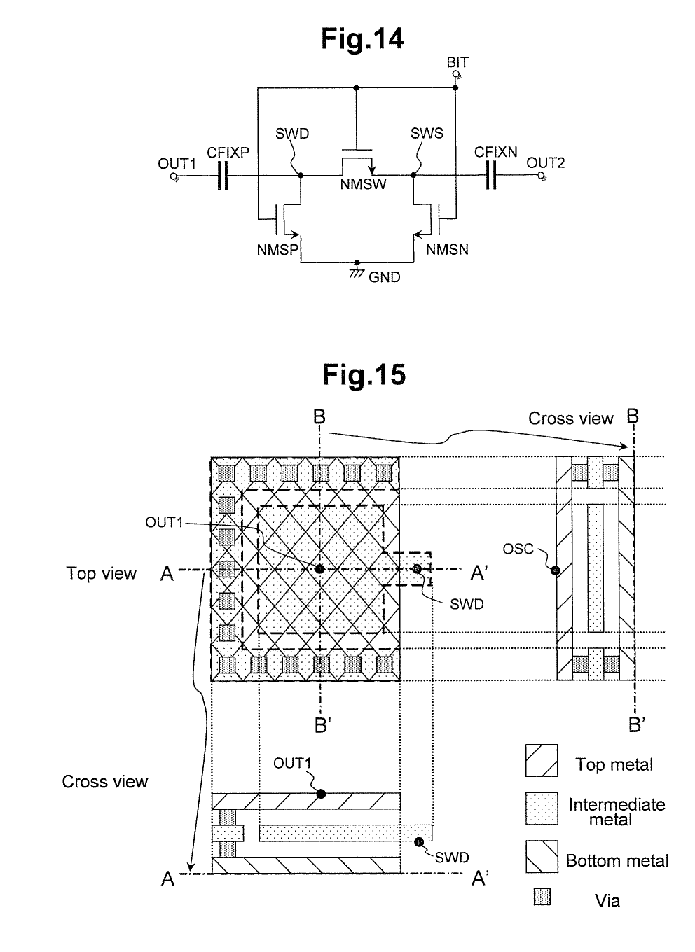

FIG. 14 is a diagram showing a further configuration of each of capacitor unit cells respectively usable as the M capacitor unit cells of the frequency coarse-tuning variable capacitor array CCT11 of the resonant circuit 10 of the digitally controlled oscillator (DCO) according to the embodiment of the present invention shown in FIG. 1 and the N capacitor unit cells of the frequency fine-tuning variable capacitor array CFT11 thereof.

In FIG. 14, the bias applying resistors RB1P and RB1N of the capacitor unit cell shown in FIG. 12 are replaced with N channel MOS transistors NMSP and NMSN. A one-bit control signal BIT is applied to gates of the switch transistors NMSP and NMSN.

FIG. 15 is a diagram showing a structure of each of the capacitors CF1XP and CF1XN of the capacitor unit cells shown in FIGS. 12 through 14. Incidentally, the capacitors CF1XP and CF1XN can be formed in the chip of the semiconductor integrated circuit by a multilayered wiring manufacturing process.

The structure of the capacitor CF1XP coupled to the first output terminal OUT1 of the digitally controlled oscillator (DCO) is shown in FIG. 15. The capacitor CF1XP is comprised of a sandwiched structure of a bottom metal, an intermediate metal and a top metal. One end of the capacitor CF1XP coupled to its corresponding drain SWD of the switch transistor NMSW is comprised of the intermediate metal located in its central part. The other end of the capacitor CF1XP coupled to the first output terminal OUT1 is comprised of the bottom metal, intermediate metal and top metal coupled by a number of via wires at the outer periphery of the capacitor CF1XP. Thus, the intermediate metal of the central part that functions as one end of the capacitor CF1XP is surrounded by external peripheral electrodes comprised of the bottom metal, intermediate metal and top metal coupled by many via wires, which functions as the other end of the capacitor CF1XP. It is thus possible to reduce the parasitic capacitance of one end of the capacitor CF1XP coupled to the drain SWD of the switch transistor NMSW.

Although not shown in FIG. 15, the capacitor CF1XN coupled to the second output terminal. OUT2 of the digitally controlled oscillator (DCO) can also be formed in a structure similar to the capacitor CF1XP having the above structure.

### <<Frequency Fine-Tuning Variable Capacitor Array>>

A frequency fine-tuning variable capacitor array CFT11 used in a tracking bank for transmission and reception comprises N capacitor unit cells CFT<0>, CFT<1> . . . CFT<N−1> respectively controlled by N-bit digital tuning control signals VFT<0>, VFT<1> . . . VFT<N−1> as shown in FIG. 1.

In particular, the capacitance values of the capacitor unit cells CFT<0>, CFT<1> . . . CFT<N−1> of the frequency fine-tuning variable capacitor array CFT11 are determined in accordance with a rule of binary weight 2^{N-1}. Thus, the capacitance of the first capacitor unit cell CFT<0> is set to a capacitance value of CF×2⁰=1 CF, the capacitance of the second capacitance unit cell CFT<1> is set to a capacitance value of CF×2¹=2 CF, the capacitance of the third capacitor unit cell CFT<2> is set to a capacitance value of CF×2²=4 CF, the capacitance of the fourth capacitor unit cell CFT<3> is set to a capacitance value of CF×2³=8 CF, and the capacitance of the Nth capacitor unit cell CFT<N−1> is set to a capacitance value of CF×2^{N-1}, respectively. In the frequency fine-tuning variable capacitor array CFT11 used in the tracking bank for transmission and reception, each unit capacitor CF is set to a relatively small value because the minimum frequency shit width is set to a small value.

The use or nonuse of the capacitors included in the capacitor unit cells of the frequency fine-tuning variable capacitor array CFT11 is determined depending on on/off of switches included in the respective capacitor unit cells Further, the N capacitor unit cells CFT<0>, CFT<1> . . . CFT<N−1> of the frequency fine-tuning variable capacitor array CFT11 can respectively be realized by the structure shown in any of FIGS. 12 through 14.

On the other hand, a problem arises in that since the respective capacitors of the tracking bank of the LC tank circuit of the conventional digital controlled oscillator (DCO) described in the non-patent document 2 have been set to the capacitance values per unit weight, the control gain K_{DCO} of the digitally controlled oscillator (DCO) varies greatly. A problem arises in that when the dynamic element matching (DEM) method is adopted to reduce the variations in the control gain, control logic circuits for controlling a large number of control lines and a large amount of capacitances become necessary, thereby increasing a chip occupied area.

In contrast to it, in the resonant circuit 10 of the digitally controlled oscillator (DCO) according to the embodiment of the present invention shown in FIG. 1 as described above, the capacitance values of the capacitor unit cells CFT<0>, CFT<1> . . . CFT<N−1> of the frequency fine-tuning variable capacitor array CFT11 used in the tracking bank for transmission and reception are respectively determined in accordance with the rule of binary weight 2^{N-1} in particular. Thus, the total capacity of the frequency fine-tuning variable capacitor array CFT11 of the tracking bank can be changed with a high degree of precision according to changes in the N-bit digital tuning control signals VFT<0>, VFT<1> . . . VFT<N−1>. As a result, the variations in the control gain K_{DCO} of the digitally controlled oscillator (DCO) can be reduced without adopting the dynamic element matching (DEM) method. Accordingly, the large number of control lines and the control logic circuits for controlling them become unnecessary and the chip occupied area can hence be reduced.

### <<Chip Layout for Binary Weight>>

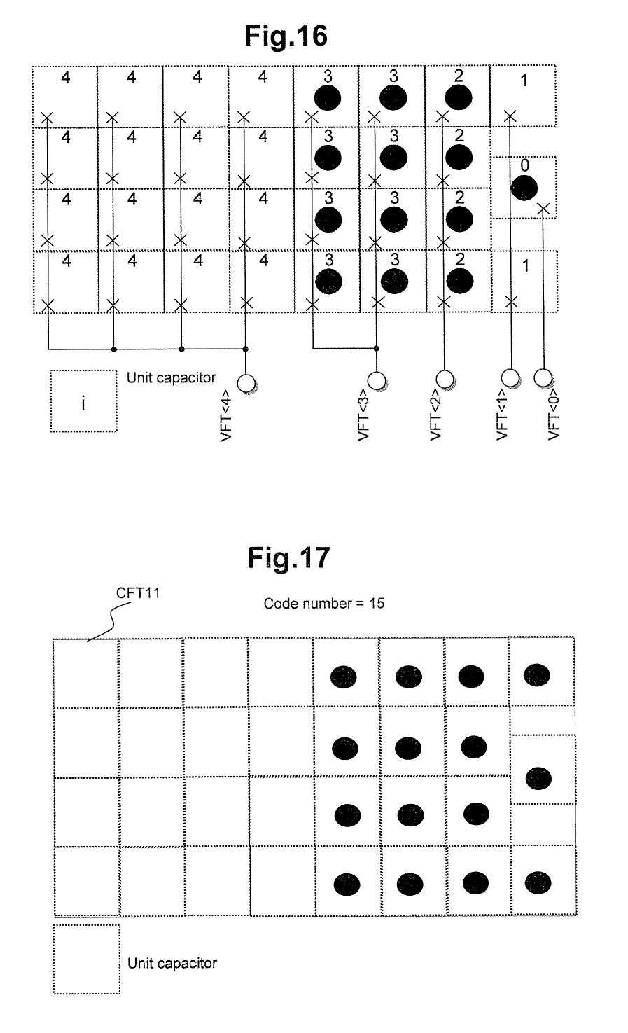

FIG. 16 is a diagram showing a configuration of a chip layout of the semiconductor integrated circuit, for setting the capacitance values of the capacitor unit cells CFT<0>, CFT<1> . . . CFT<N−1> of the frequency fine-tuning variable capacitor array CFT11 of the resonant circuit 10 of the digitally controlled oscillator (DCO) according to the embodiment of the present invention shown in FIG. 1 in accordance with the rule of binary weight 2^{N-1}.

The digital tuning control signal VFT<0> corresponding to the first bit is coupled to one unit capacitor (i=0) corresponding to the first capacitor unit cell CFT<0>. The digital tuning control signal VFT<1> corresponding to the second bit is coupled to two unit capacitors (i=1) corresponding to the second capacitor unit cell CFT<1>. The digital tuning control signal VFT<2> corresponding to the third bit is coupled to for unit capacitors (i=2) corresponding to the third capacitor unit cell CFT<2>. The digital tuning control signal VFT<3> corresponding to the fourth bit is coupled to eight unit capacitors (i=3) corresponding to the fourth capacitor unit cell CFT<3>. The digital tuning control signal VFT<4> corresponding to the fifth bit is coupled to sixteen unit capacitors (i=4) corresponding to the fifth capacitor unit cell CFT<4>.

In the example illustrated in FIG. 16, codes for the digital tuning control signals of 5 bits show an arrangement of “01101” from upper to lower bits. The eight unit capacitors (i=3) corresponding to the fourth bit, the four unit capacitors (i=2) corresponding to the third bit and the one unit capacitor (i=0) corresponding to the first bit, all of which are marked with black circles, are respectively brought to a used state by turning on of their corresponding switches. As the chip layout of the semiconductor integrated circuit, the unit capacitors identical in area to one another are used and the number of unit capacitors contained in the respective capacitor unit cells is set in accordance with the rule of binary weight 2^{N-1}. It is thus possible to accurately set the capacitance values of the capacitor unit cells in accordance with the rule of binary weight 2^{N-1}.

### <<Symmetrically-Arranged Digitally Controlled Oscillator>>

FIG. 2 is a diagram showing a configuration of a symmetrically-arranged digitally controlled oscillator (DCO) mounted in a semiconductor integrated circuit according to another embodiment of the present invention and suitable to reduce variations in its control gain K_{DCO}.

The digitally controlled oscillator (DCO) shown in FIG. 2 is different from the digitally controlled oscillator (DCO) shown in FIG. 1 in that in a resonant circuit 10 shown in FIG. 2, a frequency fine-tuning variable capacitor array CFT11 used in a tracking bank for transmission and reception comprises a first array CFT111 and a second array CFT112. Thus, capacitance values of capacitor unit cells CFT<10>, CFT<11> . . . CFT<1: N−1> of the first array CFT111 are determined in accordance with the rule of binary weight 2^{N-1}. Similarly, capacitance values of capacitor unit cells CFT<20>, CFT<21> . . . CFT<2: N−1> of the second array CFT112 are determined in accordance with the rule of binary weight 2^{N-1}.

A digital tuning control signal VFT<0> corresponding to a first bit is supplied in common to the capacitor unit cell CFT<10> of the first array CFT111 and the capacitor unit cell CFT<20> of the second array CFT112. A digital tuning control signal VFT<1> corresponding to a second bit is supplied in common to the capacitor unit cell CFT<11> of the first array CFT111 and the capacitor unit cell CFT<21> of the second array CFT112. Similarly, a digital tuning control signal VFT<N−1> corresponding to an Nth bit is supplied in common to the capacitor unit cell CFT<1: N−1> of the first array CFT111 and the capacitor unit cell CFT<2: N−1> of the second array CFT112.

Further, in the frequency fine-tuning variable capacitor array CFT11 of the digitally controlled oscillator (DCO) shown in FIG. 2, the first array CFT111 and the second array CFT112 are arranged symmetrically about a center line DD′. Namely, the capacitor unit cell CFT<10> of the first array CFT111 and the capacitor unit cell CFT<20> of the second array CFT112 are arranged symmetrically about the center line DD′. The capacitor unit cell CFT<1l> of the first array CFT111 and the capacitor unit cell CFT<21> of the second array CFT112 are arranged symmetrically about the center line DD′. Further, the capacitor unit cell CFT<1: N−1> of the first array CFT111 and the capacitor unit cell CFT<2: N−1> of the second array CFT112 are arranged symmetrically about the center line DD′.

Thus, in the digitally controlled oscillator (DCO) shown in FIG. 2, the first and second arrays CFT111 and CFT112 of the frequency fine-tuning variable capacitor array CFT11 are arranged symmetrically, so that variations in the amplitudes of differential oscillating output signals of the first and second output terminals OUT1 and OUT2 of the digitally controlled oscillator (DCO) and variations in the phase thereof can be reduced.

FIG. 3 is a diagram showing the manner in which the first array CCT111 and second array CFT112 of the frequency fine-tuning variable capacitor array CFT11 of the digitally controlled oscillator (DCO) shown in FIG. 2 are arranged symmetrically over a semiconductor chip of the semiconductor integrated circuit.

As shown in FIG. 3, the capacitor unit cell CFT<10> of the first array CFT111 and the capacitor unit cell CFT<20> of the second array CFT112 both of which are arranged symmetrically about the center line DD′, are respectively comprised of one unit capacitor (i=0). The capacitor unit cell CFT<11> of the first array CFT111 and the capacitor unit cell CFT<21> of the second array CFT112 both of which are arranged symmetrically about the center line DD′, are respectively comprised of two unit capacitors (i=1). Further, the capacitor unit cell CFT<12> of the first array CFT111 and the capacitor unit cell CFT<22> of the second array CFT112 both of which are arranged symmetrically about the center line DD′, are respectively comprised of four unit capacitors (i=2). The capacitor unit cell CFT<13> of the first array CFT111 and the capacitor unit cell CFT<23> of the second array CFT112 both of which are arranged symmetrically about the center line DD′, are respectively comprised of eight unit capacitors (i=3). Incidentally, these unit capacitors are formed in capacitance areas identical to one another.

The frequency fine-tuning variable capacitor array CFT11 having the configuration shown in FIG. 3 is included in the digitally controlled oscillator (DCO) shown in FIG. 2 in this way, so that the capacitance values of plural capacitors included in the first and second arrays CFT111 and CFT112 of the frequency fine-tuning variable capacitor array CFT11 are determined in accordance with the rule of binary weight 2^{N-1}. Thus, the total capacity of the frequency fine-tuning variable capacitor array CFT11 of the tracking bank can be changed with a high degree of precision depending on changes in the N-bit digital tuning control signals VFT<0>, VFT<1> . . . VFT<N−1>. As a result, variations in the control gain K_{DCO} of the digitally controlled oscillator (DCO) can be reduced without adopting the dynamic element matching (DEM) method. Disposing the first and second arrays CFT111 and CFT112 of the frequency fine-tuning variable capacitor array CFT11 symmetrically makes it possible to reduce variations in the amplitudes of differential oscillating output signals of the digitally controlled oscillator (DCO) and variations in the phase thereof.

<<Digitally Controlled Oscillator having Branch Signal Wires>>

FIG. 4 is a diagram showing a configuration of a digitally controlled oscillator (DCO) mounted in a semiconductor integrated circuit according to a further embodiment of the present invention and having branch signal wires suitable to reduce variations in control gain K_{DCO} thereof.

The digitally controlled oscillator (DCO) shown in FIG. 4 is different from the digitally controlled oscillator (DCO) shown in FIG. 1 in that in a resonant circuit 10 shown in FIG. 4, capacitor unit cells CFT<0>, CFT<1>, CFT<2> and CFT<3> of a frequency fine-tuning variable capacitor array CFT11 used in a tracking bank for transmission and reception respectively have branch signal wires. That is, one end of the first capacitor unit cell CFT<0>, one end of the second capacitor unit cell CFT<1>, one end of the third capacitor unit cell CFT<2> and one end of the fourth capacitor unit cell CFT<3> are respectively coupled to a first output terminal OUT1 through the independent signal wires. On the other hand, the other end of the first capacitor unit cell CFT<0>, the other end of the second capacitor unit cell CFT<1>, the other end of the third capacitor unit cell CFT<2> and the other end of the fourth capacitor unit cell CFT<3> are respectively coupled to a second output terminal OUT2 via the independent signal wires. In other words, the first output terminal OUT1 is coupled to the one end of the first capacitor unit cell CFT<0>, the one end of the second capacitor unit cell CFT<1>, the one end of the third capacitor unit cell CFT<2> and the one end of the fourth capacitor unit cell CFT<3> via the branch signal wires. On the other hand, the second output terminal OUT2 is also coupled to the other end of the first capacitor unit cell CFT<0>, the other end of the second capacitor unit cell CFT<1>, the other end of the third capacitor unit cell CFT<2> and the other end of the fourth capacitor unit cell CFT<3>.

FIG. 5 is a diagram showing a simplified equivalent circuit for examining changes in impedance due to changes in the positions of the capacitors used in the frequency fine-tuning variable capacitor array CFT11 of the digitally controlled oscillator (DCO) shown in FIG. 4 depending on changes in digital tuning control signals.

As shown in the equivalent circuit of FIG. 5, the capacitor unit cells CFT<0>, CFT<1>, CFT<2> and CFT<3> of the frequency fine-tuning variable capacitor array CFT11 are coupled to their corresponding branched independent signal wires. Thus, while the common impedance of the plural capacitor unit cells can be ignored, the sum of parasitic inductances of the capacitor unit cells becomes 3L and they become values equal to each other. Thus, even though an on state (used state) and an off state (unused state) are interchanged between any one of the capacitor unit cells CFT<0>, CFT<1>, CFT<2> and CFT<3> and another cell, the value of the total parasitic inductance remains unchanged. As a result, variations in the control gain K_{DCO} of the digitally controlled oscillator (DCO) can be reduced.

<<Digitally Controlled Oscillator having Branch Signal Wires in Symmetric Arrangement>>

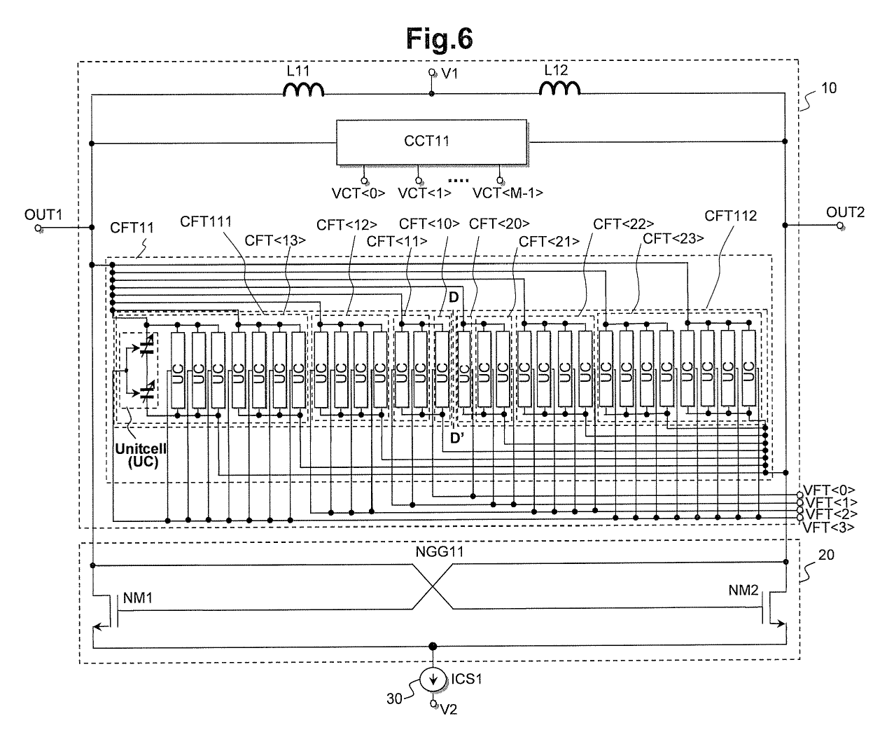

FIG. 6 is a diagram showing a configuration of a digitally controlled oscillator mounted in a semiconductor integrated circuit according to a still further embodiment of the present invention and having branch signal wires in a symmetric arrangement suitable to reduce variations in control gain K_{DCO} thereof;

Even in the case of the digitally controlled oscillator (DCO) shown in FIG. 6 in a manner similar to the digitally controlled oscillator (DCO) shown in FIG. 2, first and second arrays CFT111 and CFT112 are arranged symmetrically about a center line DD′. A capacitor unit cell CFT<10> of the first array CFT111 and a capacitor unit cell CFT<20> of the second array CFT112 are arranged symmetrically about the center line DD′ A capacitor unit cell CFT<11> of the first array CFT111 and a capacitor unit cell CFT<21> of the second array CFT112 are arranged symmetrically about the center line DD′. Further, a capacitor unit cell CFT<13> of the first array CFT111 and a capacitor unit cell CFT<23> of the second array CFT112 are arranged symmetrically about the center line DD′. Thus, since the first and second arrays CFT111 and CFT112 of the frequency fine-tuning variable capacitor array CFT11 are arranged symmetrically even in the digitally controlled oscillator (DCO) shown in FIG. 6 in a manner similar to FIG. 2, variations in the amplitudes of differential oscillating output signals of first and second output terminals OUT1 and OUT2 of the digitally controlled oscillator (DCO) and variations in the phase thereof can be reduced.

Further, even in the digitally controlled oscillator (DCO) shown in FIG. 6 in a manner similar to the digitally controlled oscillator (DCO) shown in FIG. 4, the capacitor unit cells CFT<10>, CFT<1l>, CFT<12> and CFT<13> of the first array CFT111 of the frequency fine-tuning variable capacitor array CFT11 used in a tracking bank respectively have branch signal wires, and the capacitor unit cells CFT<20>, CFT<21>, CFT<22> and CFT<23> of the second array CFT112 of the frequency fine-tuning variable capacitor array CFT11 respectively have branch signal wires. Thus, even in the digitally controlled oscillator (DCO) shown in FIG. 6 in a manner similar to FIG. 4, the value of the total parasitic inductance remains unchanged even if the positions of capacitors used depending on changes in digital tuning control signals change. It is therefore possible to reduce variations in control gain K_{DCO} of the digitally controlled oscillator (DCO).

### <<Digitally Controlled Oscillator of Sub Capacitor Array Configuration>>

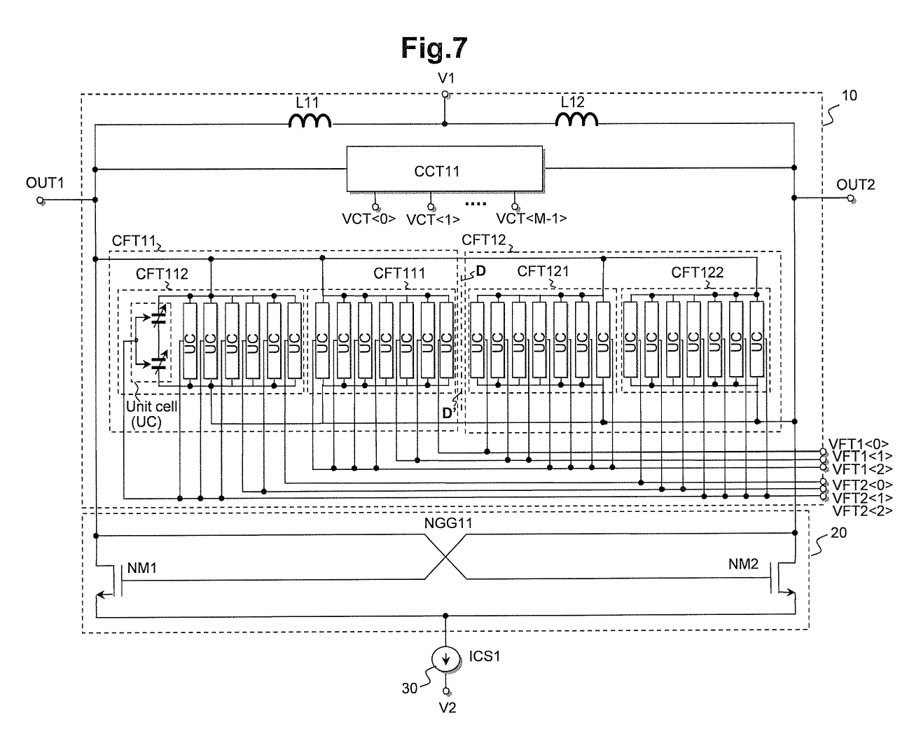

FIG. 7 is a diagram showing a configuration of a digitally controlled oscillator (DCO) mounted in a semiconductor integrated circuit according to a still further embodiment of the present invention and suitable to reduce variations in control gain K_{DCO} thereof;

The digitally controlled oscillator (DCO) shown in FIG. 7 differs from the digitally controlled oscillator (DCO) shown in FIG. 2 in that in a resonant circuit 10 shown in FIG. 7, a first frequency fine-tuning variable capacitor array CFT11 and a second frequency fine-tuning variable capacitor array CFT12 used in a tracking bank for transmission and reception are placed symmetrically about a center line DD′. Further, in the digitally controlled oscillator (DCO) shown in FIG. 7, the first capacitor array CFT11 comprises a plurality of sub capacitor arrays CFT111 and CFT112, and the second capacitor array CFT12 comprises a plurality of sub capacitor arrays CFT121 and CFT122.

The first sub capacitor array CFT111 included in the first capacitor array CFT11 and the first sub capacitor array CFT121 included in the second capacitor array CFT12 respectively include a plurality of capacitor unit cells UC supplied with first digital tuning control signals VFT1<0>, VFT1<1> and VFT1<2> of plural bits. Accordingly, the capacitance values of the first sub capacitor arrays CFT111 and CFT121 can be controlled in accordance with the rule of binary weight 2^{N-1} and the first digital tuning control signals VFT1<0>, VFT1<1> and VFT1<2> of plural bits.

The second sub capacitor array CFT112 included in the first capacitor array CFT11 and the second sub capacitor array CFT122 included in the second capacitor array CFT12 include a plurality of capacitor unit cells UC supplied with second digital tuning control signals VFT2<0>, VFT2<1> and VFT2<2> of plural bits. Thus, the capacitance values of the second sub capacitor arrays CFT112 and CFT122 can be controlled in accordance with the rule of binary weight 2^{N-1} and the second digital tuning control signals VFT2<0>, VFT2<1> and VFT2<2> of plural bits.

As a result, according to the digitally controlled oscillator (DCO) shown in FIG. 7, frequency fine tuning for transmission and reception can be executed at a tuning frequency lying in a range wider than that for the digitally controlled oscillator (DCO) shown in FIG. 2.

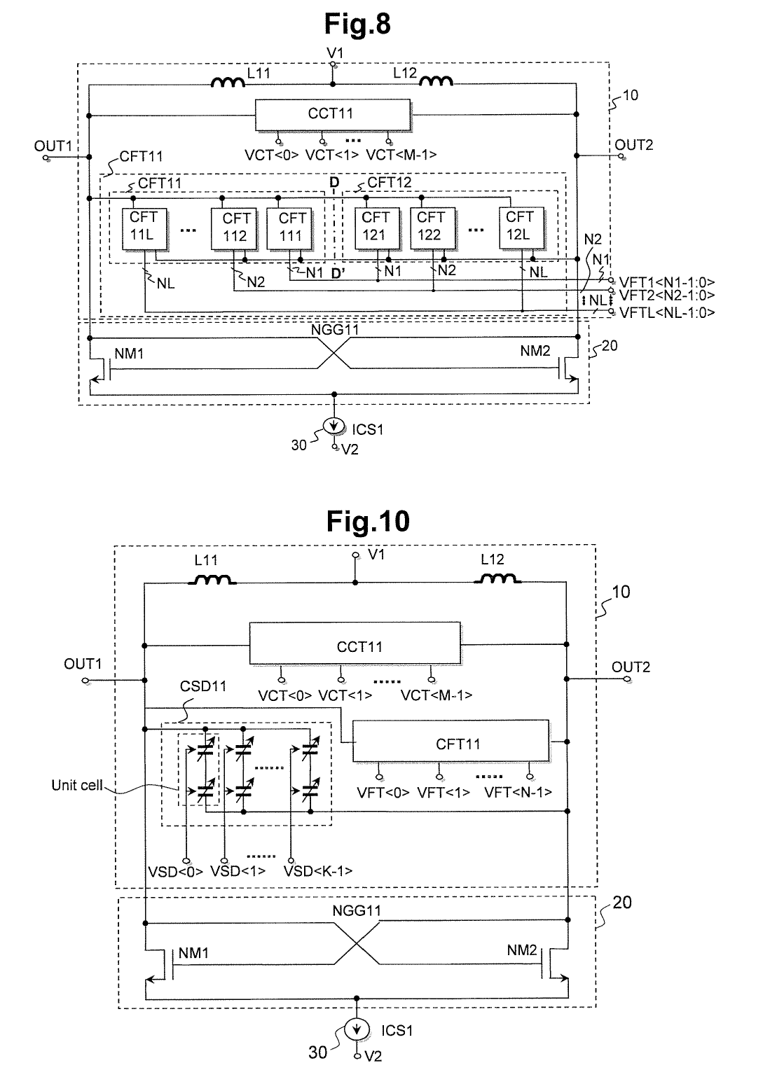

FIG. 8 is a diagram showing a configuration of a digitally controlled oscillator (DCO) mounted in a semiconductor integrated circuit according to a still further embodiment of the present invention and suitable to reduce variations in control gain K_{DCO} thereof.

The digitally controlled oscillator (DCO) shown in FIG. 8 differs from the digitally controlled oscillator (DCO) shown in FIG. 7 in that in the digitally controlled oscillator (DCO) shown in FIG. 8, a plurality of sub capacitor arrays included in a first capacitor array CFT11 are expanded to CFT111, CFT112 . . . CFT111, and a plurality of sub capacitor arrays included in a second capacitor array CFT12 are expanded to CFT121, CFT122 . . . CFT12L.

Even in FIG. 8, the capacitance values of the first sub capacitance arrays CFT111 and CFT121 are controlled in accordance with first digital tuning control signals VFT1<0>, VFT1<1> and VFT1<N1−1> of N1 bits and a rule of binary weight 2^{N2-1}. The capacitance values of the second sub capacitance arrays CFT112 and CFT122 are controlled in accordance with first digital tuning control signals VFT<0>, VFT2<1> and VFT2<N2−1> of N2 bits and a rule of binary weight 2^{N2-1} Similarly, the capacitance values of the Lth sub capacitor arrays CFT11L and CFT12L are controlled in accordance with first digital tuning control signals VFTL<0>, VFTL<1> and VFTL<N2−1> of L bits and a rule of binary weight 2^{L-1}. Even in the digitally controlled oscillator (DCO) shown in FIG. 8, frequency fine tuning for transmission and reception can be carried out at a wide range of tuning frequencies in a manner similar to the digitally controlled oscillator (DCO) shown in FIG. 7.

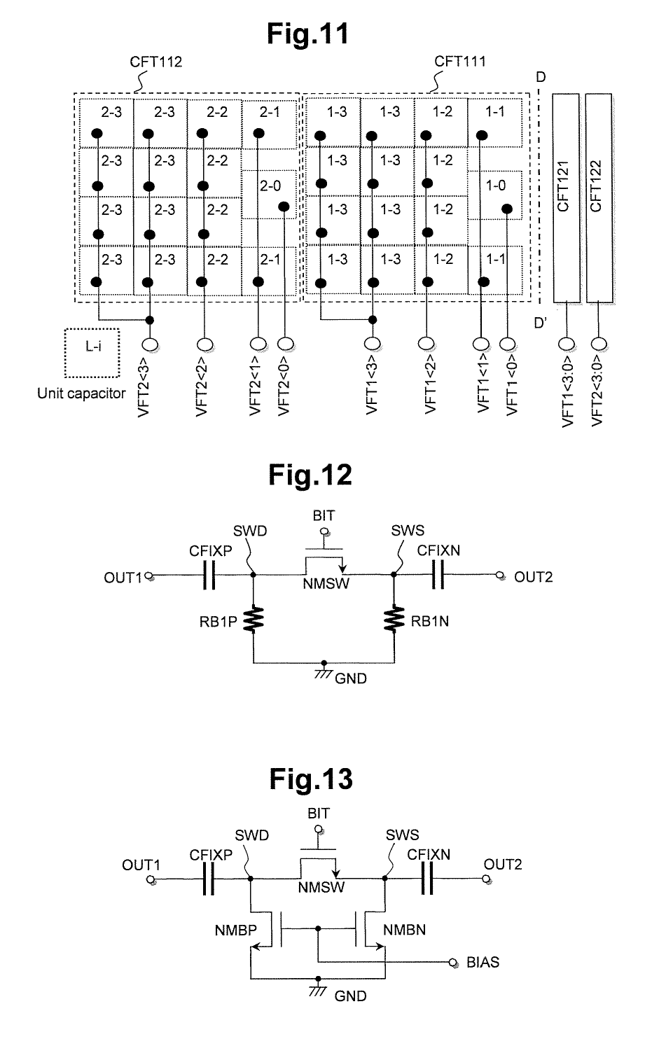

FIG. 11 is a diagram showing the manner in which the sub capacitor arrays CFT111, CFT112, CFT121 and CFT122 of the digitally controlled oscillator (DCO) according to the still further embodiment of the present invention shown in FIG. 7 are laid out in the semiconductor integrated circuit.

In FIG. 11, the sub capacitor array CFT111 and the sub capacitor array CFT121 are arranged symmetrically about the center line DD′. The sub capacitor array CFT112 and the sub capacitor array CFT122 are arranged symmetrically about the center line DD′. In the configuration shown in FIG. 11, a state in which eight unit capacitors are used, is realized by bringing only one, e.g., the sub capacitor array CFT111 of the four sub capacitor arrays CFT111, CFT112, CFT121 and CFT122 to a used state and thereby bringing only the control signal VFT1<3> corresponding to the fourth bit of the first digital tuning control signals VFT1<0>, VFT1<1>, VFT1<2>and VFT1<3> to a high level “1”. In FIG. 11, the state in which the eight unit capacitors are used, can be realized even by bringing only two, e.g., the sub capacitor arrays CFT111 and CFT112 of the four sub capacitor arrays to a used state respectively and thereby bringing only the control signal VFT1<2> corresponding to the third bit, of the first digital tuning control signals and the control signal VFT2<2> corresponding to the third bit, of the second digital tuning control signals to the high level “1” respectively. Further, in FIG. 11, another state in which eight unit capacitors are used, can be realized even by bringing the four sub capacitor arrays CFT111, CFT112, CFT121 and CFT122 to a used state respectively and thereby bringing only the control signal VFT1<1> corresponding to the second bit, of the first digital tuning control signals and the control signal VFT2<1> corresponding to the second bit, of the second digital tuning control signals to the high level “1”.

FIG. 17 is a diagram for describing the conditions of use of plural capacitor unit cells where the number of control codes of digital tuning control signals is 15 in a system based on capacitance values per unit weight of the capacitor unit cells of the frequency fine-tuning variable capacitor array CFT11 used in the tracking bank of the digitally controlled oscillator shown in FIG. 1.

When the number of the control codes is 15, fifteen capacitor unit cells (unit capacitors) arranged on the right side of the frequency fine-tuning variable capacitor array CFT11 of FIG. 17 and marked with black circles are in a used state.

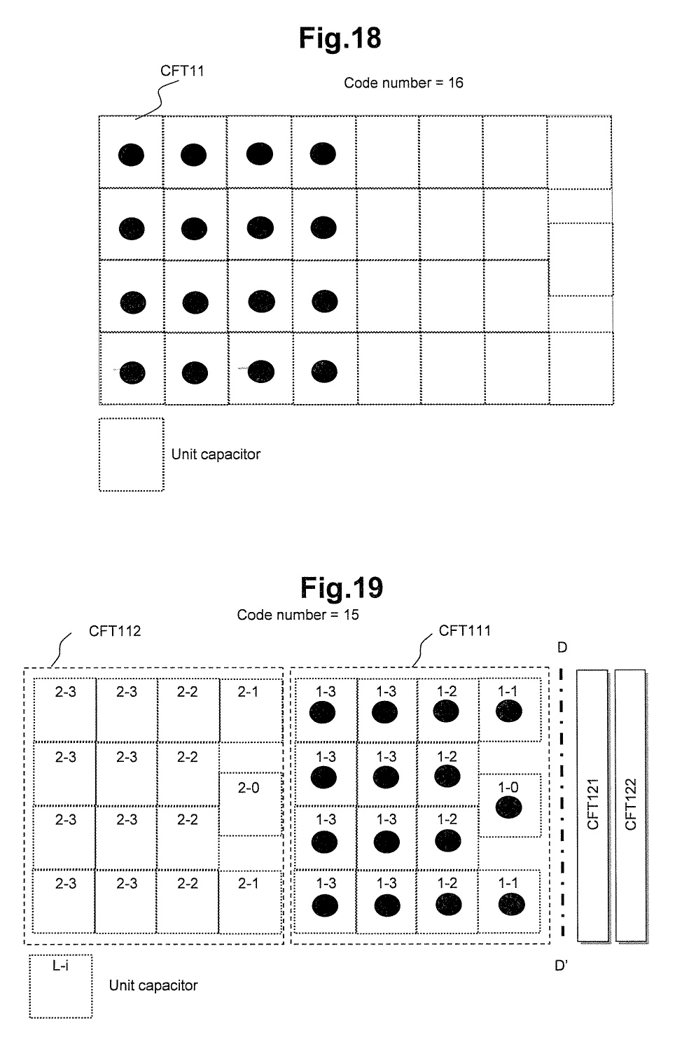

FIG. 18 is a diagram for describing the conditions of use of plural capacitor unit cells where the number of control codes of digital tuning control signals is 16 in the system based on the capacitance values per unit weight of the capacitor unit cells of the frequency fine-tuning variable capacitor array CFT11 used in the tracking bank of the digitally controlled oscillator (DCO) shown in FIG. 1.

When the number of control codes is 16, sixteen capacitor unit cells (unit capacitors) arranged on the left side of the frequency fine-tuning variable capacitor array CFT11 of FIG. 18 and marked with black circles are in a used state.

When FIGS. 17 and 18 are compared with each other, one control code of the digital tuning control signals is simply increased and the layouts of capacitor unit cells placed in a used state and capacitor unit cells placed in an unused state vary greatly. Consequently, a problem arises in that since the value of each parasitic inductance also varies greatly, the control gain K_{DCO} of the digitally controlled oscillator (DCO) under the system based on the capacitance values per unit weight varies greatly.

FIG. 19 is a diagram for describing the conditions of use of capacitor unit cells where the number of control codes of digital tuning control signals is 15 in the sub capacitor arrays CFT111 and CFT112 of the digitally controlled oscillator (DCO) according to the still further embodiment of the present invention shown in FIG. 7.

When the number of the control codes is 15, fifteen capacitor unit cells (unit capacitors) arranged in the sub capacitor array CFT111 on the right side of FIG. 19 and marked with black circles are in a used state.

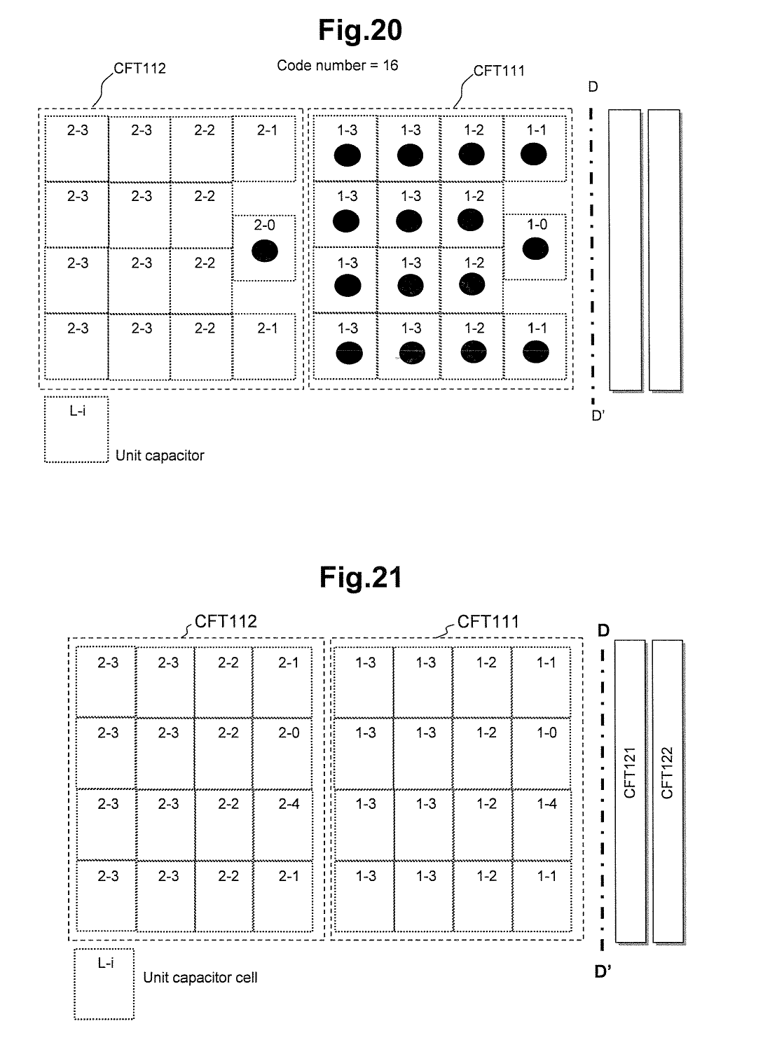

FIG. 20 is a diagram for describing the conditions of use of capacitor unit cells where the number of control codes of digital tuning control signals is 16 in the sub capacitor arrays CFT111 and CFT112 of the digitally controlled oscillator (DCO) according to the still further embodiment of the present invention shown in FIG. 7.

When the number of the control codes is 16, the fifteen capacitor unit cells (unit capacitors) arranged in the sub capacitor array CFT111 on the right side of FIG. 19 and marked with the black circles are not merely in the used state, but one capacitor unit cell (unit capacitor) arranged in the sub capacitor array CFT112 on the left side and marked with a black circle is additionally brought to a used state. One capacitor unit cell of the sub capacitor array CFT112 on the left side is placed in a used state additionally assuming that the control signal VFT2<0> corresponding to the first bit, of the second digital tuning control signals is brought to a high level “1”.

When FIGS. 19 and 20 are compared with each other, each of changes in the layouts of both each capacitor unit cell placed in the used state and each capacitor unit cell placed in the unused state is merely brought to the state in which one capacitor unit cell is used additionally, even though one control code of the control codes of the digital tuning control signals is increased Thus, an advantage is brought about in that since a change in the value of each parasitic inductance is also small, variations in the control gain K_{DCO} of the digitally controlled oscillator (DCO) under the system based on the capacitance values per binary weight can be rendered small.

In order to use the digitally controlled oscillator (DCO) including the sub capacitor arrays CFT111 and CFT112 of the frequency fine-tuning variable capacitor array CFT11 based on the control system shown in each of FIGS. 19 and 20 in an all digital PLL (AD-PLL), there is a need to decode an output signal of a digital loop filter (DLF) of AD-PLL and supply its result to the digitally controlled oscillator (DCO).

FIG. 21 is a diagram showing a configuration of sub capacitor arrays CFT111 and CFT112 of the frequency fine-tuning variable capacitor array CFT11, which have been improved in consideration of its use in all digital PLL (AD-PLL) of the digitally controlled oscillator (DCO) according to the embodiment shown in FIG. 7.

Compared with FIGS. 19 and 20 as shown in FIG. 21, one capacitor unit cell (1-4) controlled by a control signal VFT1<4> corresponding to a fifth bit, of the first digital tuning control signals is added to the sub capacitor array CFT111, and one capacitor unit cell (2-4) controlled by a control signal VFT2<4> corresponding to a fifth bit, of the second digital tuning control signals is added to the sub capacitor array CFT112 in FIG. 21.

Consequently, since the control signals of lower 4 bits in the first and second digital tuning control signals can be made the same as before their improvements, an improvement in the configuration of a decoder supplied with the digital loop filter (DLF) of AD-PLL becomes easy.

Since one capacitor unit cell (1-4) is added to the sub capacitor array CFT111 as shown in FIG. 21, the one capacitor unit cell (1-4) added thereto is selected where the number of control codes of the digital control signals is 16. The corresponding capacitor unit cell of the sub capacitor array CFT112 on the left side is selected where the number of control codes is brought to 17 or more.

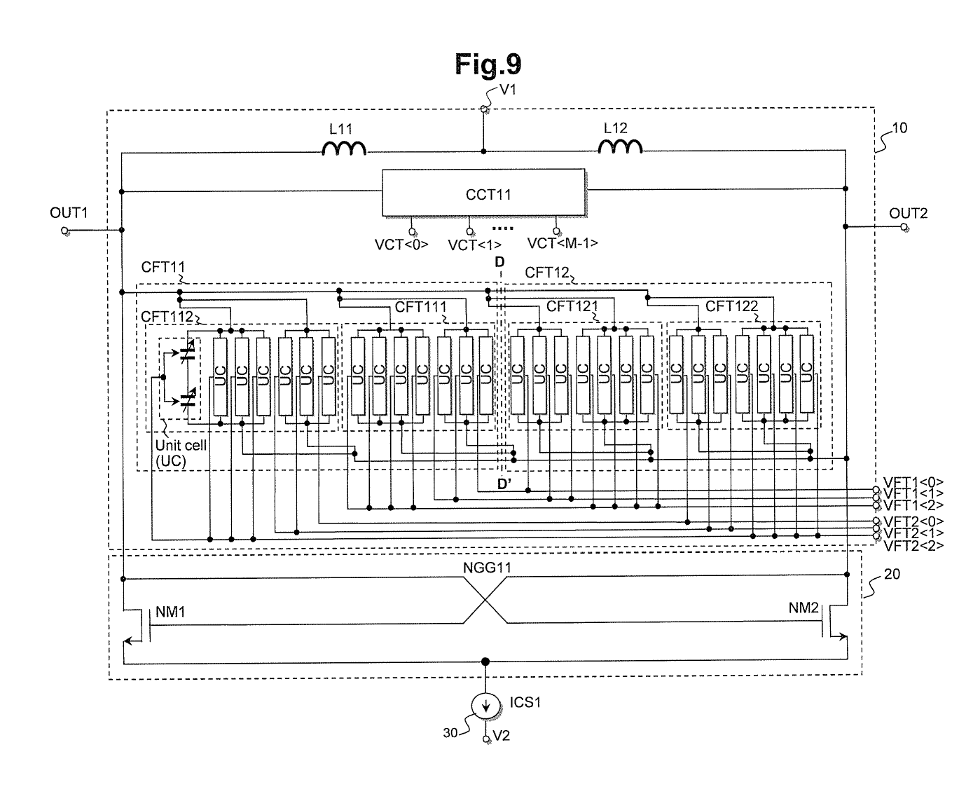

FIG. 9 is a diagram showing a configuration of a digitally controlled oscillator (DCO) mounted in a semiconductor integrated circuit according to a still further embodiment of the present invention and suitable to reduce variations in control gain K_{DCO} thereof.

The digitally controlled oscillator (DCO) shown in FIG. 9 is different from the digitally controlled oscillator (DCO) shown in FIG. 7 in that a plurality of capacitor unit cells lying inside sub capacitor arrays CFT111, CFT112, CFT121 and CFT122 of a frequency fine-tuning variable capacitor array CFT11 used in a tracking bank respectively have branch signal wires. Thus, even though use and unused states are interchanged between the capacitor unit cells, a change in the value of each parasitic inductance becomes smaller so that variations in control gain K_{DCO} of the digitally controlled oscillator (DCO) can be reduced.

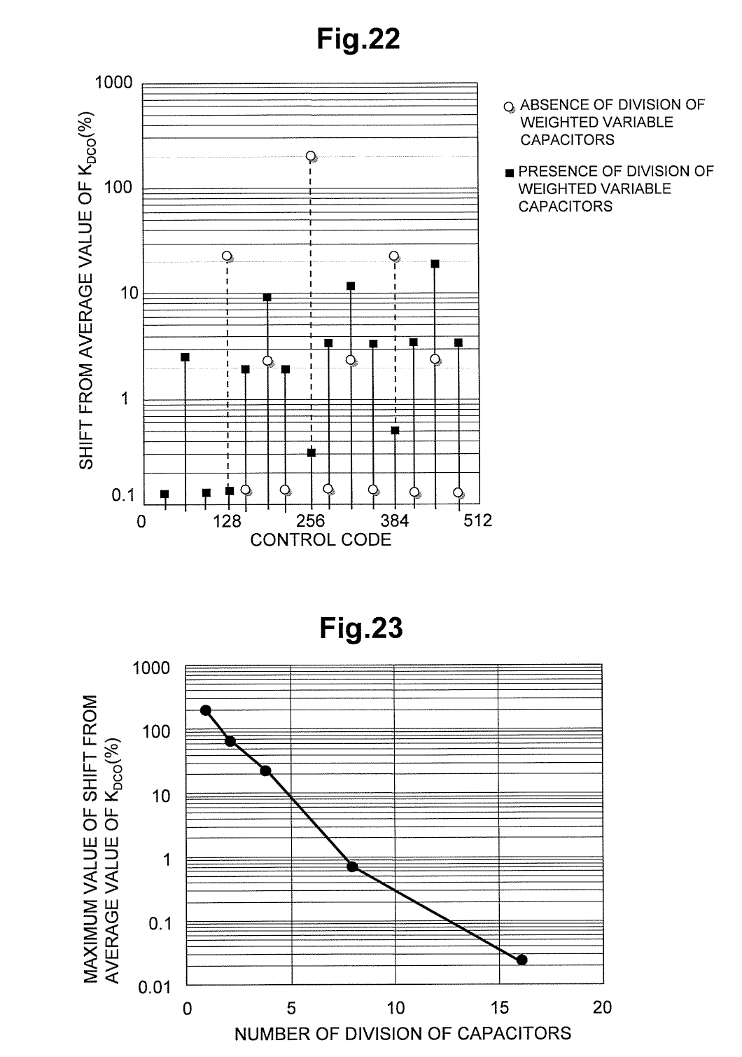

As described above, each of the frequency fine-tuning variable capacitor arrays CFT11 of the digitally controlled oscillators (DCO) according to the various embodiments of the present invention has been divided into the plural arrays or plural sub capacitor arrays FIG. 22 is a diagram illustrating the effect of reducing variations in control gain K_{DCO} by array division or sub capacitor array division of each of the frequency fine-tuning variable capacitor arrays of the digitally controlled oscillators (DCO) according to the various embodiments of the present invention.

In FIG. 22, each of white circles shows where the arrays of the frequency fine-tuning variable capacitor array CFT11 are comprised of a single array without its array division. A variation in control gain K_{DCO} corresponding to 194% at the maximum occurs. In FIG. 22, each of black squares shows where the arrays of the frequency fine-tuning variable capacitor array CFT11 are divided into four. It can be understood that the maximum of a variation in control gain K_{DCO} is 21% and hence the amounts of variations in control gain are reduced. The black squares show the results of calculations that the arrays of the frequency fine-tuning variable capacitor array CFT11 are divided into eight or more thereby to allow the variations in control gain K_{DCO} to be reduced to an approximately 1% or less.

FIG. 23 is a diagram showing the effect of reducing variations in control gain K_{DCO} by array division or sub capacitor array division of each of the frequency fine-tuning variable capacitor arrays CFT11 of the digitally controlled oscillators (DCO) according to the various embodiments of the present invention in a manner similar to FIG. 22.

It is understood that as shown in FIG. 23, a variation in control gain K_{DCO} can be reduced to an approximately 1% or less by division of arrays into eight, and a variation in control gain K_{DCO} can be reduced to an approximately 0.02% by division of the arrays into sixteen.

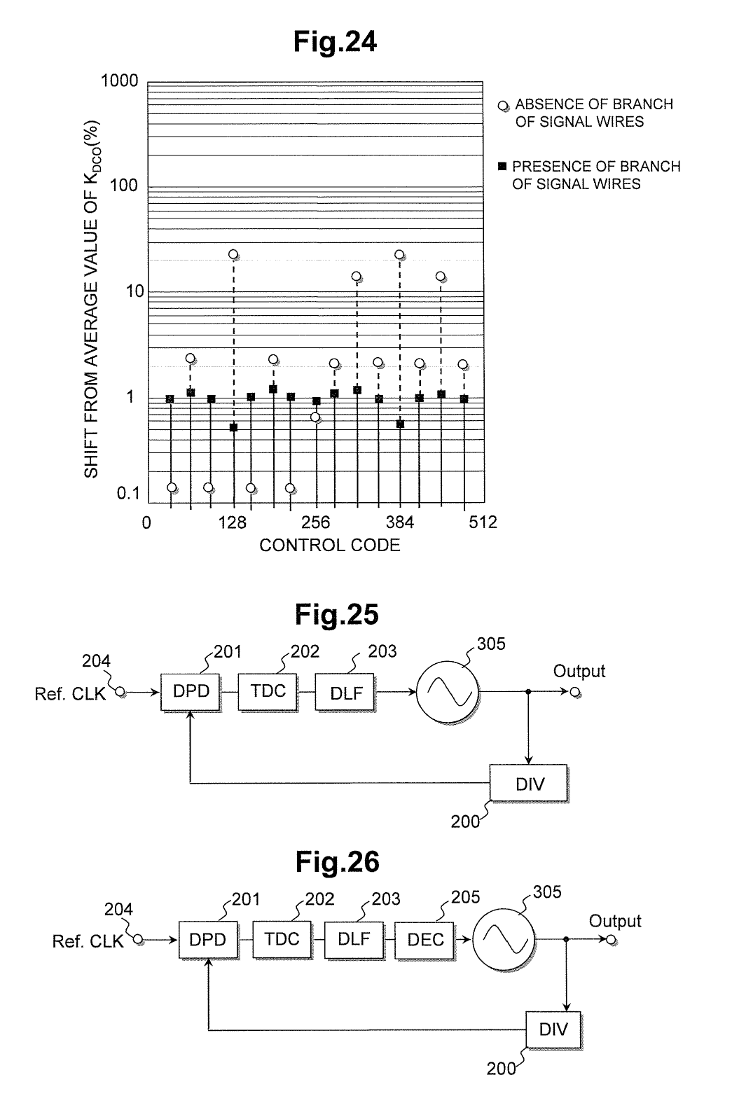

FIG. 24 is a diagram showing the effect of reducing variations in control gain K_{DCO} by the frequency fine-tuning variable capacitor arrays of the digitally controlled oscillators according to the embodiments of the present invention being divided into plural form and taken as branch signal wires as shown in FIGS. 6 and 9.

In FIG. 24, the division number of the variable capacitor array is 2. White circles show where the frequency fine-tuning variable capacitor array CFT11 is taken as for a common signal wire or line without making branch signal wires. They result in large variations in control gain K_{DCO}, which go beyond 10%. On the other hand, black squares show where the frequency fine-tuning variable capacitor array CFT11 is taken as for branch signal wires. It can be understood that small variations in control gain K_{DCO} corresponding to an approximately 1% occur.

### <<Tracking Bank for Decimal Part>>

FIG. 10 is a diagram showing a configuration of a symmetrically-arranged digitally controlled oscillator (DCO) mounted in a semiconductor integrated circuit according to a still further embodiment of the present invention and suitable to reduce variations in control gain K_{DCO} thereof and reduce phase noise.

The digitally controlled oscillator (DCO) shown in FIG. 10 differs from the digitally controlled oscillators (DCO) shown in FIGS. 1, 2, 4, 6, 7, 8 and 9 in that a variable capacitor array CSD11 is added which functions as a tracking bank for a decimal part supplied with output signals of a ΣΔ converter responsive to minority bits for the tracking bank used between transmission and reception.

K capacitor unit cells per unit weight supplied with K-bit controls signals VSD<0>, VSD<1> . . . VSD<K−1> are included in the variable capacitor array CSD11. Since the output signals of the ΣΔ converter are supplied to the K-bit control signals VSD<0>, VSD<1> . . . VSD<K−1> of the variable capacitor array CSD11 as the minority bits for the tracking bank, the capacitance values of the variable capacitor array CDS11 are controlled.

Spurious tones generated from the digitally controlled oscillator (DCO) shown in FIG. 10 with the variable capacitor array CSD11 included in a resonant circuit 10 are diffused into second-order and third-order harmonics of the ΣΔ converter.

### <<Digital PLL>>

FIG. 25 is a diagram showing a configuration of a digital PLL mounted in a semiconductor integrated circuit according to another embodiment of the present invention and including a digitally controlled oscillator (DCO) in which variations in control gain K_{DCO} thereof have been reduced.

In the digital PLL (Phase Locked Loop) shown in FIG. 25, an output signal of the digitally controlled oscillator (DCO) 305 is divided into frequencies of 1/n (where n: real number greater than or equal to 1) by a divider (DIV) 200. The divided signal from the divider (DIV) 200 and a reference signal 204 are supplied to a phase frequency detector (PDP) 201, where the frequencies or phases of both signals or the frequencies and phases are compared. An output of the phase frequency detector (PDP) 201 is supplied to a digital loop filter (DLF) 203 via a time-to-digital converter (TDC) 202. A control output signal of the digital loop filter (DLF) 203 is supplied to a phase frequency control input terminal of the digitally controlled oscillator (DCO) 305.

With a negative feedback loop of the digital PLL shown in FIG. 25, the frequency of the oscillation output signal of the digitally controlled oscillator (DCO) 305 is locked to n times the frequency of the reference signal 204.

The digitally controlled oscillator (DCO) in which the variations in its control gain K_{DCO} have been reduced, which is shown in any of FIGS. 1, 2, 4, 6, 7, 8, 9 and 10, can be used for the digitally controlled oscillator (DCO) 305 included in the digital PLL shown in FIG. 25. As a result, phase noise and errors of the output signal of the digital PLL shown in FIG. 25 can be reduced. Further, the number of control lines for frequency control of the digitally controlled oscillator (DCO) 305 is cut down, whereby a chip occupied area of the digital PLL can be reduced.

FIG. 26 is a diagram showing a configuration of a digital PLL mounted in a semiconductor integrated circuit according to a further embodiment of the present invention and including a digitally controlled oscillator (DCO) in which variations in control gain K_{DCO} thereof have been reduced.

The digital PLL shown in FIG. 26 differs from the digital PLL shown in FIG. 25 in that in the digital PLL shown in FIG. 26, a decoder (DEC) 205 is added between a control output signal of a digital loop filter (DLF) 203 and a phase frequency control input terminal of the digitally controlled oscillator (DCO) 305.

The decoder (DEC) 205 added to the digital PLL shown in FIG. 26 corresponds to the addition of one capacitor unit cell (1-4) to the sub capacitor array CFT111 and the addition of one capacitor unit cell (2-4) to the sub capacitor array CFT112 in the embodiment of the present invention described in FIG. 21.

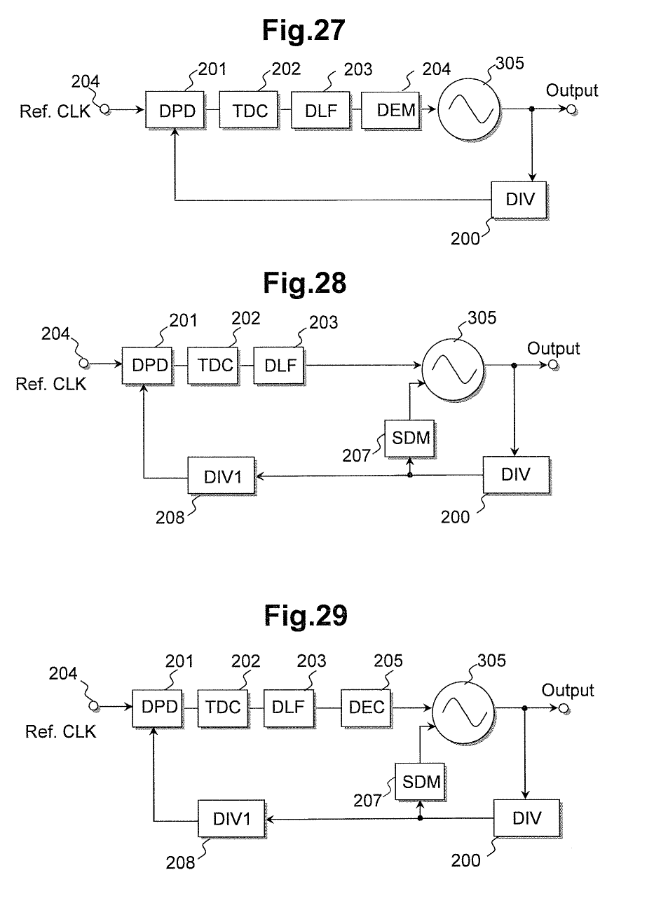

FIG. 27 is a diagram showing a configuration of a digital PLL mounted in a semiconductor integrated circuit according to a still further embodiment of the present invention and including a digitally controlled oscillator (DCO) in which variations in control gain K_{DCO} thereof have been reduced;

The digital PLL shown in FIG. 27 differs from the digital PLL shown in FIG. 25 in that in the digital PLL shown in FIG. 27, a dynamic element matching circuit (DEM) 204 is added between a control output signal of a digital loop filter (DLF) 203 and a phase frequency control input terminal of the digitally controlled oscillator (DCO) 305.

The dynamic element matching circuit (DEM) 204 added to the digital PLL shown in FIG. 27 corresponds to an improvement in linearity of frequency conversion relative to the K-bit control signals due to capacitance errors of the K capacitor unit cells per unit weight included in the variable capacitor array CSD11 that functions as the following band for the decimal part supplied with the output signals of the ΣΔ converter in the embodiment of the present invention described in FIG. 10.

FIG. 28 is a diagram showing a configuration of a digital PLL mounted in a semiconductor integrated circuit according to a still further embodiment of the present invention and including a digitally controlled oscillator (DCO) in which variations in control gain K_{DCO} thereof have been reduced.

The digital PLL shown in FIG. 28 is different from the digital PLL shown in FIG. 25 in that in the digital PLL shown in FIG. 28, a second divider (DIV1) 208 is added between a divider (DIV) 200 and a phase frequency detector (PDP) 201, and a ΣΔ converter (SDM) 204 is added between the divider (DIV) 200 and a digitally controlled oscillator (DCO) 305.

The ΣΔ converter (SMD) 204 added to the digital PLL shown in FIG. 28 drives the K-bit control signals VSD<0>, VSD<1> . . . VSD<K−1> coupled to the K capacitor unit cells per unit weight of the variable capacitor array CSD11 in the embodiment of the preset invention described in FIG. 10. Thus, since spurious tones generated from the digitally controlled oscillator (DCO) included in the digital PLL shown in FIG. 28 are diffused into second-order and third-order harmonics of the ΣΔ converter, phase noise can be reduced.

FIG. 29 is a diagram illustrating a configuration of a digital PLL mounted in a semiconductor integrated circuit according to a still further embodiment of the present invention and including a digitally controlled oscillator (DCO) in which variations in control gain K_{DCO} thereof have been reduced.

The digital PLL shown in FIG. 29 is different from the digital PLL shown in FIG. 28 in that in the digital PLL shown in FIG. 29, a decoder (DEC) 205 is added between a control output signal of a digital loop filter (DLF) 203 and a phase frequency control input terminal of the digitally controlled oscillator (DCO) 305.

The decoder (DEC) 205 added to the digital PLL shown in FIG. 29 corresponds to the addition of one capacitor unit cell (1-4) to the sub capacitor array CFT111 and the addition of one capacitor unit cell (2-4) to the sub capacitor array CFT112 in the embodiment of the present invention described in FIG. 21.

### <<Wireless Receiver>>

FIG. 30 is a diagram showing a configuration of a wireless receiver mounted in a semiconductor integrated circuit according to a still further embodiment of the present invention and including a digitally controlled oscillator (DCO) or a digital PLL in which variations in control gain K_{DCO} thereof have been reduced.

In the heterodyne radio receiver shown in FIG. 30, an RF receive signal received by an antenna 301 is supplied to one input terminal of a receiving mixer 303 after having been amplified by a low noise amplifier 302. A reception local signal is supplied from the digitally controlled oscillator (DCO) 305 to the other input terminal of the receiving mixer 303 thereby to generate an intermediate frequency receive signal from the output of the receiving mixer 303. An intermediate frequency (IF) of the intermediate frequency receive signal becomes a frequency corresponding to a difference between the RF receive signal and the reception local signal.

Unnecessary frequency components are attenuated from the intermediate frequency receive signal by a bandpass filter 306 and thereafter amplified by an intermediate frequency amplifier 307, after which a reception baseband signal is formed at a demodulator (DEMOD) 308. The reception baseband signal is supplied to an external baseband circuit, and a control signal for controlling an oscillation frequency of the digitally controlled oscillator (DCO) 305 is supplied from the baseband circuit to a control circuit 304.

In the heterodyne wireless receiver shown in FIG. 30, the digitally controlled oscillator (DCO) in which the variations in the control gain K_{DCO} have been reduced, which is shown in any of FIGS. 1, 2, 4, 6, 7, 8, 9 and 10, can be used as the digitally controlled oscillator (DCO) 305 for generating the reception local signal. Further, the digital PLL shown in any of FIGS. 25, 26, 27, 28 and 29 as the control circuit 304 for controlling the oscillation frequency of the digitally controlled oscillator (DCO) 305 can be used as a PLL frequency synthesizer.

FIG. 31 is a diagram showing a configuration of a wireless receiver mounted in a semiconductor integrated circuit according to a still further embodiment of the present invention and including a digitally controlled oscillator (DCO) or a digital PLL in which variations in control gain K_{DCO} thereof have been reduced.

In the direct downconversion wireless receiver shown in FIG. 31, an RF receive signal received by an antenna 301 is amplified by a low noise amplifier 302 and thereafter supplied to one input terminals of two receiving mixers 303a and 303b. The other input terminal of the one receiving mixer 303a is supplied directly with an I-phase reception local signal from the digitally controlled oscillator (DCO) 305, whereas the other input terminal of the other receiving mixer 303b is supplied with a Q-phase reception local signal from the digitally controlled oscillator (DCO) 305 via a 90° phase shifter Thus, an I-phase reception baseband signal and a Q-phase reception baseband signal are generated from the outputs of the two receiving mixers 303a and 303b. Unnecessary frequency component of the I-phase and Q-phase reception baseband signals are attenuated i by bandpass filters 306a and 306b, and thereafter the I-phase and Q-phase reception baseband signals are amplified by amplifiers 307a and 307b respectively, which in turn are supplied to a baseband circuit. A control signal for controlling an oscillation frequency of the digitally controlled oscillator (DCO) 305 is supplied from the baseband circuit to a control circuit 304.

Since the frequency conversion of the direct downconversion (DDC) from the RF receive signal to the reception baseband signal is carried out at the two receiving mixers 303a and 303b of the direct conversion wireless receiver shown in FIG. 31, the DDC system is also called “zero IF system”. The term zero IF means that an intermediate frequency is a baseband zero frequency.

In the DDC wireless receiver shown in FIG. 31, the digitally controlled oscillator (DCO) in which the variations in the control gain K_{DCO} have been reduced, which is shown in any of FIGS. 1, 2, 4, 6, 7, 8, 9 and 10, can be used as the digitally controlled oscillator (DCO) 305 for generating the reception local signal. Further, the digital PLL shown in any of FIGS. 25, 26, 27, 28 and 29 as the control circuit 304 for controlling the oscillation frequency of the digitally controlled oscillator (DCO) 305 can be used as a PLL frequency synthesizer.

FIG. 32 is a diagram illustrating a configuration of a wireless receiver mounted in a semiconductor integrated circuit according to a still further embodiment of the present invention and including a digitally controlled oscillator (DCO) or a digital PLL in which variations in control gain K_{DCO} thereof have been reduced.

In the sliding IF wireless receiver shown in FIG. 32, an RF receive signal received by an antenna 301 is amplified by a low noise amplifier 302 and thereafter supplied to one input terminal of a first receiving mixer 303. A reception local signal is supplied from the digitally controlled oscillator (DCO) 305 to the other input terminal of the first receiving mixer 303 thereby to generate an intermediate frequency receive signal from the output of the first receiving mixer 303.

The intermediate frequency receive signal from the first receiving mixer 303 is supplied to one input terminal of a second receiving mixer 303i and one input terminal of a third receiving mixer 303q. The reception local signal from the digitally controlled oscillator (DCO) 305 is supplied to an input terminal of a ½ divider 360 so that divided reception local signals having a phase difference of 90° are generated from the outputs of the ½ divider 360, which in turn are supplied to the other input terminals of the second receiving mixer 303i and the third receiving mixer 303q.

Thus, an I-phase reception baseband signal and a Q-phase reception baseband signal are generated from the outputs of the receiving mixers 303i and 303q. The I-phase and Q-phase reception baseband signals are respectively amplified by amplifiers 307i and 307q and supplied to a baseband circuit. A control circuit 304 is supplied with a control signal for controlling an oscillation frequency of the digitally controlled oscillator (DCO) 305 from the baseband circuit.

In the sliding IF wireless receiver shown in FIG. 32, the digitally controlled oscillator (DCO) in which the variations in the control gain K_{DCO} have been reduced, which is shown in any of FIGS. 1, 2, 4, 6, 7, 8, 9 and 10, can be used as the digitally controlled oscillator (DCO) 305 for generating the reception local signal. Further, the digital PLL shown in any of FIGS. 25, 26, 27, 28 and 29 as the control circuit 304 for controlling the oscillation frequency of the digitally controlled oscillator (DCO) 305 can be used as a PLL frequency synthesizer.

### <<Wireless Transceiver>>

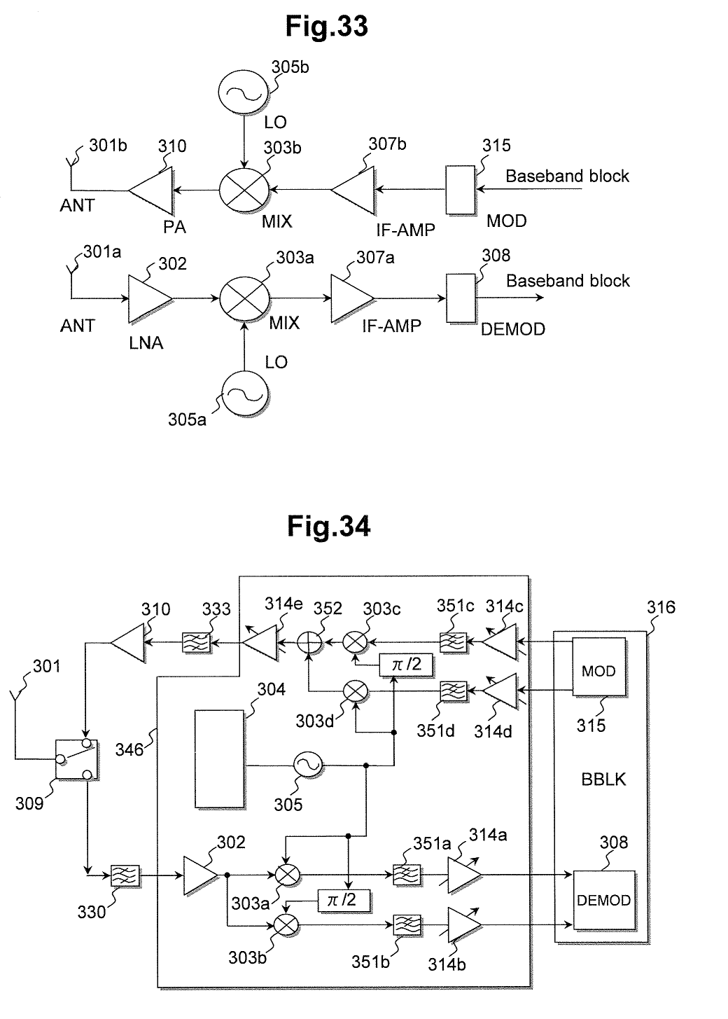

FIG. 33 is a diagram showing a configuration of a wireless transceiver mounted in a semiconductor integrated circuit according to a still further embodiment of the present invention and including a digitally controlled oscillator (DCO) or a digital PLL in which variations in control gain K_{DCO} thereof have been reduced.

In the heterodyne wireless transceiver shown in FIG. 33, an RF receive signal received by an antenna 301a is amplified by a low noise amplifier 302 and thereafter supplied to one input terminal of a receiving mixer 303a, The other input terminal of the receiving mixer 303a is supplied with a reception local signal of a digitally controlled oscillator (DCO) 305a thereby to generate an intermediate frequency receive signal from the receiving mixer 303a. An intermediate frequency of the intermediate frequency receive signal becomes a frequency corresponding to a difference between the RF receive signal and the reception local signal. The intermediate frequency receive signal is amplified by an intermediate frequency amplifier 307a and a reception baseband signal is formed by a demodulator (DEMOD) 308. The reception baseband signal is supplied to an external baseband circuit.

Upon transmission, a transmission baseband signal generated from the baseband circuit is modulated by a modulator (MOD) 315 and amplified by an intermediate frequency amplifier 307b, followed by being supplied to one input terminal of a transmitting mixer 303b. The other input terminal of the transmitting mixer 303b is supplied with a transmission local signal of a digitally controlled oscillator (DCO) 305b thereby to generate an RF transmit signal from the transmitting mixer 303b. An RF frequency of the RF transmit signal becomes a frequency corresponding to the sum of an intermediate frequency transmit signal and the transmission local signal. A local oscillation signal output from the oscillator 305b of the present invention is inputted to the mixer 303b. The RF transmit signal from the transmitting mixer 303b is amplified by a high output amplifier 310 and thereafter transmitted from an antenna 301b.

In the heterodyne wireless transceiver shown in FIG. 33, the digitally controlled oscillator (DCO) in which the variations in the control gain K_{DCO}, which is shown in any of FIGS. 1, 2, 4, 6, 7, 8, 9 and 10, can be used as the first digitally controlled oscillator (DCO) 305a and the second digitally controlled oscillator (DCO) 305b, which generate the reception and transmission local signals respectively. Further, the digital PLL shown in any of FIGS. 25, 26, 27, 28 and 29 as each of control circuits for controlling the oscillation frequencies of the digitally controlled oscillators (DCO) 305a and 305b, can be used as a PLL frequency synthesizer.

FIG. 34 is a diagram showing a configuration of a wireless transceiver mounted in a semiconductor integrated circuit according to a still further embodiment of the present invention and including a digitally controlled oscillator (DCO) or a digital PLL in which variations in control gain K_{DCO} thereof have been reduced.

The wireless transceiver shown in FIG. 34 comprises a direct down conversion (DDC) wireless receiver and a direct up conversion (DUC) wireless transmitter.

Upon reception, unnecessary frequency component of an RF receive signal received by an antenna 301 and having passed through an antenna switch 309 (SW) is attenuated by a bandpass filter 330, and thereafter, the RF receive signal is amplified by a low noise amplifier 302, after which it is supplied to one input terminals of two receiving mixers 303a and 303b.

The other input terminal of the one receiving mixer 303a is supplied directly with an I-phase reception local signal from the digitally controlled oscillator (DCO) 305, whereas the other input terminal of the other receiving mixer 303b is supplied with a Q-phase reception local signal from the digitally controlled oscillator (DCO) 305 via a 90° phase shifter π/2.

Thus, an I-phase reception baseband signal and a Q-phase reception baseband signal are generated from the outputs of the two receiving mixers 303a and 303b. The I-phase and Q-phase reception baseband signals are attenuated in unnecessary frequency component by low pass filters 351a and 351b and thereafter amplified by gain control amplifiers 314a and 314b respectively. The reception baseband signals from the gain control amplifiers 314a and 314b are supplied to a baseband circuit 316, where a receive signal is generated by a demodulator 308. A control signal for controlling an oscillation frequency of the digitally controlled oscillator (DCO) 305 which generates a reception local signal, is supplied from the baseband circuit 316 to a control circuit 304.

Upon transmission, I-phase and Q-phase transmission baseband signals generated from a modulator (MOD) 315 of the baseband circuit 316 are respectively amplified by gain control amplifiers 314c and 314d and attenuated in unnecessary frequency component by low pass filters 351c and 351d, after which they are supplied to one input terminals of transmitting mixers 303c and 303d.

The other input terminal of the one transmitting mixer 303d is supplied directly with an I-phase transmission local signal from the digitally controlled oscillator (DCO) 305, whereas the other input terminal of the other transmitting mixer 303c is supplied with a Q-phase transmission local signal from the digitally controlled oscillator (DCO) 305 via a 90° phase shifter π/2.

Thus, output signals of the two transmitting mixers 303c and 303d are combined together by an adder 352 thereby to generate an RF transmit signal The RF transmit signal is amplified by a gain control amplifier 314e and attenuated in unnecessary frequency component by a bandpass filer 333, followed by being amplified by a high output amplifier 310, which in turn is transmitted from the antenna 301 via the antenna switch 309 (SW).

In the wireless transceiver operated as the direct downconversion (DDC) receiver shown in FIG. 34 and operated as the direct upconversion (DUC) transmitter shown in FIG. 34, the digitally controlled oscillator (DCO) in which the variations in the control gain K_{DCO}, which is shown in any of FIGS. 1, 2, 4, 6, 7, 8, 9 and 10, can be used as the digitally controlled oscillator (DCO) 305 which generates the reception local signal and the transmission local signal respectively. Further, the digital PLL shown in any of FIGS. 25, 26, 27, 28 and 29 as the control circuit 304 for controlling the oscillation frequency of the digitally controlled oscillator (DCO) 305, can be used as a PLL frequency synthesizer.

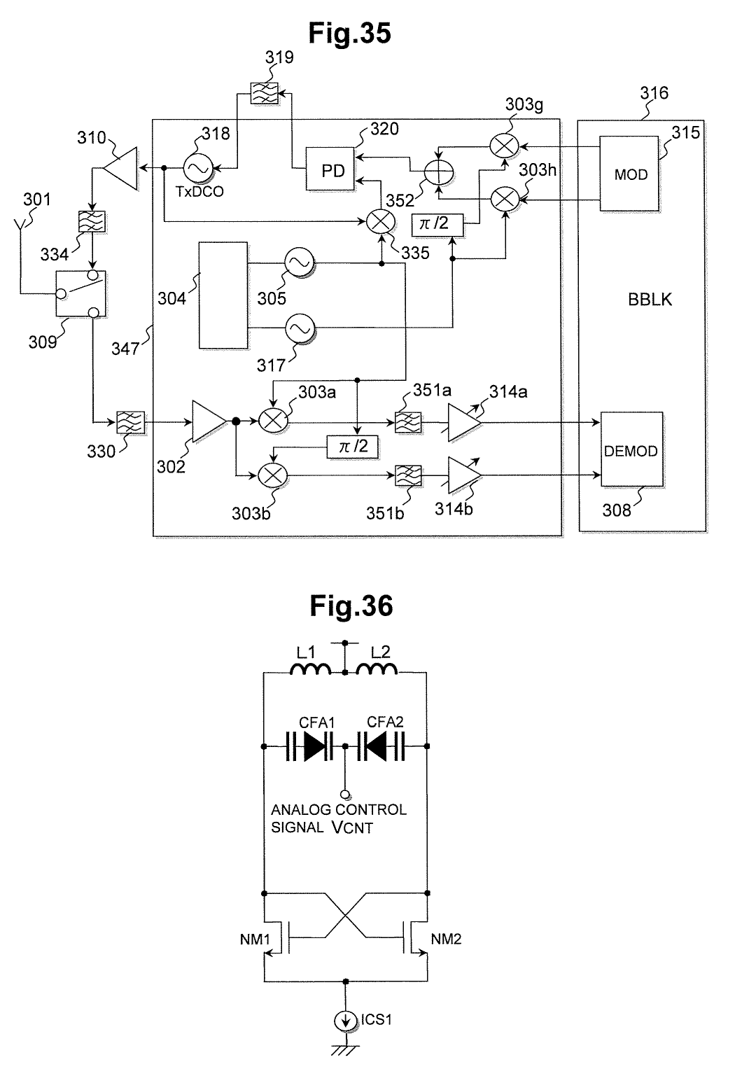

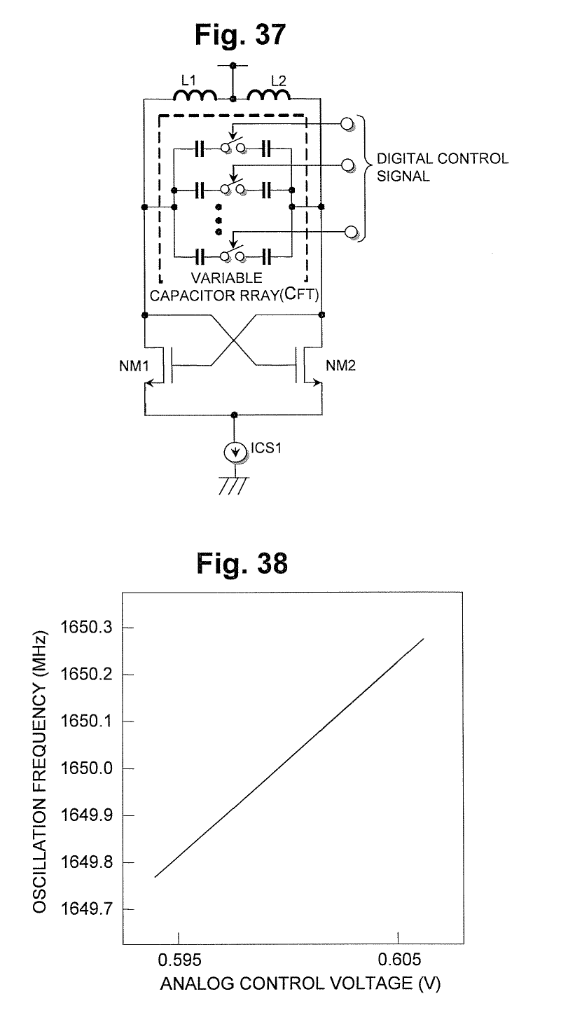

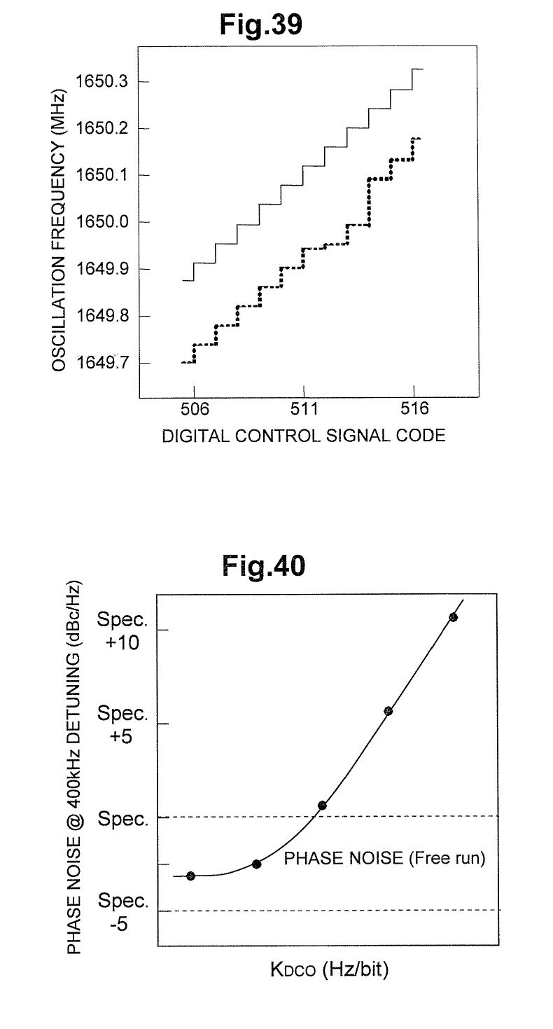

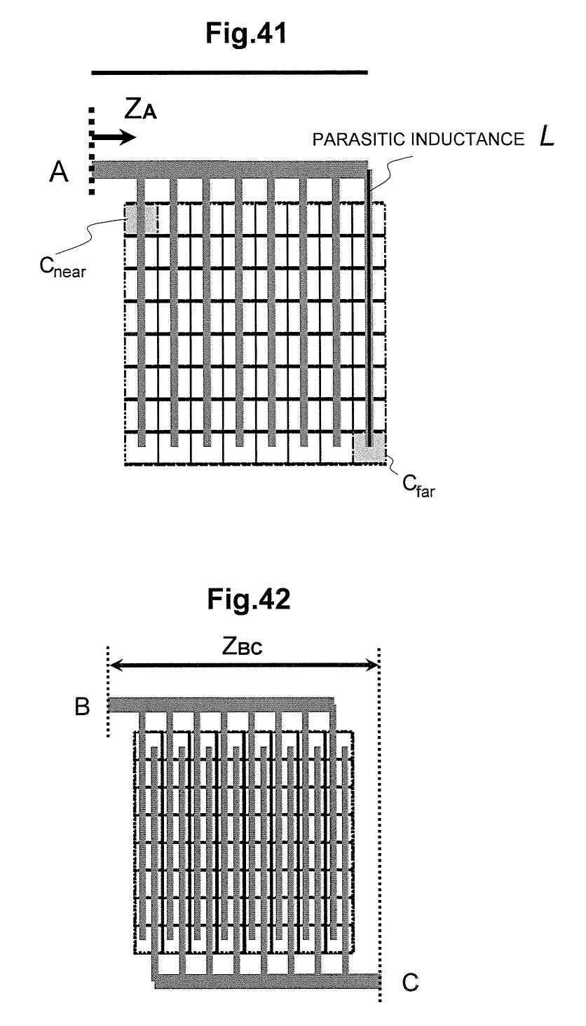

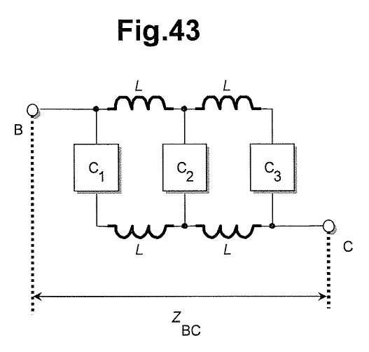

FIG. 35 is a diagram illustrating a configuration of a wireless transceiver mounted in a semiconductor integrated circuit according to a still further embodiment of the present invention and including a digitally controlled oscillator (DCO) or a digital PLL in which variations in control gain K_{DCO} thereof have been reduced.

The wireless transceiver shown in FIG. 35 comprises an offset PLL wireless transmitter and a direct downconversion (DDC) wireless receiver.

The DDC wireless receiver included in the wireless transceiver shown in FIG. 35 comprises a bandpass filter 330, a low noise amplifier 302, receiving mixers 303a and 303b, a 90° phase shifter π/2, low pass filters 351a and 351b and gain control amplifiers 314a and 314b. Thus, since the configuration and receiving operation of the DDC wireless receiver included in the wireless transceiver shown in FIG. 35 are exactly the same as those of the DDC wireless receiver included in the wireless transceiver shown in FIG. 34.

Upon transmission, the transmitting operation of the offset PLL wireless transmitter is executed. That is, I-phase and Q-phase transmission baseband signals generated from a modulator (MOD) 315 of a baseband circuit 316 are respectively supplied to one input terminals of transmitting mixers 303g and 303h.

The other input terminal of the one transmitting mixer 303h is supplied directly with an I-phase transmission intermediate frequency signal from a transmission digitally controlled oscillator (DCO) 317, whereas the other input terminal of the other transmitting mixer 303g is supplied with a Q-phase transmission intermediate frequency signal from the transmission digitally controlled oscillator (DCO) 317 via a 90° phase shifter π/2. Intermediate frequency output signals of the transmitting mixers 303g and 303h are vector-combined by an adder 352, after which the result of combination is supplied to one input terminal of the phase detector (PD) 320. An output signal of the phase detector 320 is supplied to an input terminal of a digitally controlled oscillator (DCO) 318 served as a transmission controlled oscillator TxDCO after unnecessary frequency components thereof have been removed by a bandpass filter 319.

An RF transmit signal generated from the transmission digitally controlled oscillator (DCO) 318 is amplified by a high output amplifier 310 and thereafter transmitted from an antenna 301 via an antenna switch 309 (SW). Further, one input terminal of a down mixer 335 is supplied with the RF transmit signal, whereas the other input terminal of the down mixer 335 is supplied with a high frequency signal generated from a digitally controlled oscillator (DCO) 305. Thus, an intermediate frequency feedback signal is generated from an output terminal of the down mixer 335 and supplied to the other input terminal of the phase detector (PD) 320. With feedback control of the phase detector (PD) 320, filter 319, oscillator (DCO) 318 and down mixer 335 of the offset PLL, the phase and frequency of the RF transmit signal are controlled accurately by the phase and frequency of the intermediate frequency signal supplied to one input terminal of the phase detector (PD) 320 from the adder 352.

In the wireless transceiver including the offset PLL wireless transmitter and the direct downconversion (DDC) wireless receiver both shown in FIG. 35, the digitally controlled oscillator (DCO) in which the variations in the control gain K_{DCO} have been reduced, which is shown in any of FIGS. 1, 2, 4, 6, 7, 8, 9 and 10, can be used as the three digitally controlled oscillators (DCO) 305, 317 and 318 used for the transmitting and receiving operations. Further, the digital PLL shown in any of FIGS. 25, 26, 27, 28 and 29 as the control circuit 304 for controlling the oscillation frequencies of the two digitally controlled oscillators (DCO) 305 and 317 can be used as a PLL frequency synthesizer.

While the invention made above by the present inventors has been described specifically on the basis of the preferred embodiments, the present invention is not limited to the embodiments. It is needless to say that various changes can be made thereto within the scope not departing from the gist thereof.

For example, the cross-coupled transistors for performing the oscillation operation by the digitally controlled oscillator (DCO) of the present invention and the switch transistors of the capacitor unit cells are not limited to only the use of the MOS transistors. Needless to say, the MOS transistors can obtain similar advantageous effects even if the MOS transistors are replaced with, for example, other field effect transistors, bipolar transistors, heterodyne bipolar transistors and high electron mobility transistors.

What is claimed is:

1. A semiconductor integrated circuit comprising:
a digitally controlled oscillator,
wherein the digitally controlled oscillator comprises oscillation transistors and a resonant circuit,
wherein the resonant circuit comprises inductances, a frequency coarse-tuning variable capacitor array and a frequency fine-tuning variable capacitor array,
wherein the frequency coarse-tuning variable capacitor array at least comprises a plurality of coarse-tuning capacitor unit cells corresponding to a first predetermined number, which are respectively controlled by coarse-tuning digital control signals having the number of bits corresponding to the first predetermined number,
wherein the frequency fine-tuning variable capacitor array at least comprises a plurality of fine-tuning capacitor unit cells corresponding to a second predetermined number, which are respectively controlled by fine-tuning digital control signals having the number of bits corresponding to the second predetermined number,
wherein capacitance values of the coarse-tuning capacitor unit cells of the frequency coarse-tuning variable capacitor array are set in accordance with a binary weight, and
wherein capacitance values of the fine-tuning capacitor unit cells of the frequency fine-tuning variable capacitor array are set in accordance with a binary weight.

2. The semiconductor integrated circuit according to claim 1,
wherein a minimum frequency transition width of the frequency fine-tuning variable capacitor array is set smaller than that of the frequency coarse-tuning variable capacitor array.

3. The semiconductor integrated circuit according to claim 2,
wherein the frequency fine-tuning variable capacitor array comprises a plurality of capacitor arrays controlled by the fine-tuning digital control signals respectively.

4 The semiconductor integrated circuit according to claim 3,
wherein the capacitor arrays are arranged symmetrically about a center line.

5. The semiconductor integrated circuit according to claim 2,
wherein the fine-tuning capacitor unit cells of the frequency fine-tuning variable capacitor array respectively comprise unit capacitors corresponding to a number set in accordance with a binary weight, and
wherein the unit capacitors respectively have capacitance areas identical to one another.

6. The semiconductor integrated circuit according to claim 2,
wherein the oscillation transistors at least comprise a first transistor and a second transistor, and the inductances at least comprise a first inductance and a second inductance,
wherein an output electrode of the first transistor and a control input electrode of the second transistor are coupled to one end of the first inductance, whereas an output electrode of the second transistor and a control input electrode of the first transistor are coupled to one end of the second inductance,
wherein the other end of the first inductance and the other end of the second inductance are coupled to an operating potential point, and
wherein the frequency coarse-tuning variable capacitor array and the frequency fine-tuning variable capacitor array are coupled in parallel between the one end of the first inductance and the one end of the second inductance.

7. The semiconductor integrated circuit according to claim 6,
wherein one ends of unit cells of the fine-tuning capacitor unit cells of the frequency fine-tuning variable capacitor array are respectively coupled to the one end of the first inductance through independent first branch signal wires, and
wherein the other ends of the unit cells of the fine-tuning capacitor unit cells of the frequency fine-tuning variable capacitor array are respectively coupled to the one end of the second inductance through independent second branch signal wires.

8. The semiconductor integrated circuit according to claim 6,
wherein unit cells of the coarse-tuning capacitor unit cells of the frequency coarse-tuning variable capacitor array and unit cells of the fine-tuning capacitor unit cells of the frequency fine-tuning variable capacitor array respectively comprise first capacitors whose one ends are coupled to the one end of the first inductance, second capacitors whose one ends are coupled to the one end of the second inductance, and switching transistors each coupled between the other end of the first capacitor and the other end of the second capacitor.

9. The semiconductor integrated circuit according to claim 6,
wherein the digitally controlled oscillator is provided in a digital PLL comprising a phase frequency detector, a digital loop filter and a divider, and
wherein an oscillation frequency of the digitally controlled oscillator is controlled by an output of the digital loop filter.

10. The semiconductor integrated circuit according to claim 9, further comprising at least either one of a receiver for receiving an RF receive signal therein and generating a reception baseband signal by frequency downconversion, and a transmitter for generating an RF transmit signal by frequency upconversion of a transmission baseband signal,
wherein the digital PLL is operated as a frequency synthesizer for generating at least either one of a reception local signal based on the frequency downconversion of the receiver and a transmission local signal based on the frequency upconversion of the transmitter.

11. A semiconductor integrated circuit comprising:
a digitally controlled oscillator,
wherein the digitally controlled oscillator comprises oscillation transistors and a resonant circuit,
wherein the resonant circuit comprises inductances, a channel selection acquiring variable capacitor array and a follow-up tuning variable capacitor array,
wherein the channel selection acquiring variable capacitor array at least comprises a plurality of channel selection acquiring capacitor unit cells corresponding to a first predetermined number, which are respectively controlled by channel selection acquisition digital control signals having the number of bits corresponding to the first predetermined number,
wherein the follow-up tuning variable capacitor array at least comprises a plurality of follow-up tuning capacitor unit cells corresponding to a second predetermined number, which are respectively controlled by follow-up tuning digital control signals having the number of bits corresponding to the second predetermined number,
wherein capacitance values of the channel selection acquiring capacitor unit cells of the channel selection acquiring variable capacitor array are set in accordance with a binary weight, and
wherein capacitance values of the follow-up tuning capacitor unit cells of the follow-up tuning variable capacitor array are set in accordance with a binary weight.

12. The semiconductor integrated circuit according to claim 11,
wherein a minimum frequency transition width of the follow-up tuning variable capacitor array is set smaller than that of the channel selection acquiring variable capacitor array.

13. The semiconductor integrated circuit according to claim 12,
wherein the follow-up tuning variable capacitor array comprises a plurality of capacitor arrays respectively controlled by the follow-up tuning digital control signals.

14. The semiconductor integrated circuit according to claim 13,
wherein the capacitor arrays are arranged symmetrically about a center line.

15. The semiconductor integrated circuit according to claim 12,
wherein the follow-up tuning capacitor unit cells of the follow-up tuning variable capacitor array are respectively comprised of unit capacitors corresponding to a number set in accordance with a binary weight, and
wherein the unit capacitors respectively have capacitance areas identical to one another.

16. The semiconductor integrated circuit according to claim 12,
wherein the oscillation transistors at least comprise a first transistor and a second transistor, and the inductances at least comprise a first inductance and a second inductance,
wherein an output electrode of the first transistor and a control input electrode of the second transistor are coupled to one end of the first inductance, whereas an output electrode of the second transistor and a control input electrode of the first transistor are coupled to one end of the second inductance,
wherein the other end of the first inductance and the other end of the second inductance are coupled to an operating potential point, and
wherein the channel selection acquiring variable capacitor array and the follow-up tuning variable capacitor array are coupled in parallel between the one end of the first inductance and the one end of the second inductance.

17. The semiconductor integrated circuit according to claim 16,
wherein one ends of unit cells of the follow-up tuning capacitor unit cells of the follow-up tuning variable capacitor array are respectively coupled to the one end of the first inductance through independent first branch signal wires, and
wherein the other ends of the unit cells of the follow-up tuning capacitor unit cells of the follow-up tuning variable capacitor array are respectively coupled to the one end of the second inductance through independent second branch signal wires.

18. The semiconductor integrated circuit according to claim 16,
wherein unit cells of the channel selection acquiring capacitor unit cells of the channel selection acquiring variable capacitor array, and unit cells of the follow-up tuning capacitor unit cells of the follow-up tuning variable capacitor array respectively comprise first capacitors whose one ends are coupled to the one end of the first inductance, second capacitors whose one ends are coupled to the one end of the second inductance, and switching transistors each coupled between the other end of the first capacitor and the other end of the second capacitor.

19. The semiconductor integrated circuit according to claim 16,
wherein the digitally controlled oscillator is provided in a digital PLL comprising a phase frequency detector, a digital loop filter and a divider, and
wherein an oscillation frequency of the digitally controlled oscillator is controlled by an output of the digital loop filter.

20. The semiconductor integrated circuit according to claim 19, further comprising at least either one of a receiver for receiving an RF receive signal therein and generating a reception baseband signal by frequency downconversion, and a transmitter for generating an RF transmit signal by frequency upconversion of a transmission baseband signal,
wherein the digital PLL is operated as a frequency synthesizer for generating at least either one of a reception local signal based on the frequency downconversion of the receiver and a transmission local signal based on the frequency upconversion of the transmitter.
